(19) United States
(12) Patent Application Publication
(10) Pub. No.: US 2022/0342311 A1
(43) Pub. Date: Oct. 27, 2022

(54) INFORMATION PROCESSING DEVICE, INFORMATION PROCESSING METHOD, AND SEMICONDUCTOR MANUFACTURING SYSTEM

(71) Applicant: Gigaphoton Inc., Tochigi (JP)

(72) Inventors: Yutaka IGARASHI, Oyama-shi (JP); Satoru KIKUCHI, Oyama-shi (JP); Kunihiko ABE, Oyama-shi (JP); Yuji MINEGISHI, Oyama-shi (JP)

(73) Assignee: Gigaphoton Inc., Tochigi (JP)

(21) Appl. No.: 17/858,674

(22) Filed: Jul. 6, 2022

Related U.S. Application Data
(63) Continuation of application No. PCT/JP2020/005336, filed on Feb. 12, 2020.

(51) Int. Cl. G03F 7/20; H01S 5/00

(52) U.S. Cl. CPC G03F 7/20; H01S 5/0014

(57) ABSTRACT

An information processing device includes a processor and a storage device. The processor is configured to acquire data for each parameter provided from each of a light source device which generates pulse light and an exposure apparatus which performs exposure on a wafer with the pulse light output from the light source device, and time data associated with the data; to perform classification, based on the acquired data and time data, for each record of the data associated with same time data for distinguishing whether being data during exposure in which the wafer is irradiated with the pulse light or being data during non-exposure; to associate attribute information indicating an attribute according to the classification with each of the records; to cause the storage device to store the data and the time data associated with the attribute information; and to generate a chart using data read from the storage device.

### CROSS-REFERENCE TO RELATED APPLICATIONS

The present application claims the benefit of International Application No. PCT/JP2020/005336, filed on Feb. 12, 2020 the entire contents of which are hereby incorporated by reference.

### BACKGROUND

### 1. Technical Field

The present disclosure relates to an information processing device, an information processing method, and a semiconductor manufacturing system.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser device for exposure, a KrF excimer laser device for outputting laser light having a wavelength of about 248 nm and an ArF excimer laser device for outputting laser light having a wavelength of about 193 nm are used.

The KrF excimer laser device and the ArF excimer laser device each have a large spectral line width of about 350 to 400 pm in natural oscillation light. Therefore, when a projection lens is formed of a material that transmits ultraviolet rays such as KrF laser light and ArF laser light, there is a case in which chromatic aberration occurs. As a result, the resolution may decrease. Then, a spectral line width of laser light output from the gas laser device needs to be narrowed to the extent that the chromatic aberration can be ignored. For this purpose, there is a case in which a line narrowing module (LNM) including a line narrowing element (etalon, grating, and the like) is provided in a laser resonator of the gas laser device to narrow a spectral line width. In the following, a gas laser device with a narrowed spectral line width is referred to as a line narrowing gas laser device.

### LIST OF DOCUMENTS

### Patent Documents

Patent Document 1: Japanese Patent Application Publication No. 2008-98282
Patent Document 2: International Publication No. WO2019/043780
Patent Document 3: Japanese Patent Application Publication No. 2006-237052

### SUMMARY

An information processing device according to an aspect of the present disclosure includes a processor and a storage device. Here, the processor is configured to acquire data for each parameter provided from each of a light source device which generates pulse light and an exposure apparatus which performs exposure on a wafer with the pulse light output from the light source device, and time data associated with the data; to perform classification, based on the acquired data and time data, for each record of the data associated with same time data for distinguishing whether being data during exposure in which the wafer is irradiated with the pulse light or being data during non-exposure other than during the exposure; to associate attribute information indicating an attribute according to the classification with each of the records; to cause the storage device to store the data and the time data associated with the attribute information; and to generate a chart using data read from the storage device.

An information processing method according to another aspect of the present disclosure is a method to be executed by a processor. Here, the method includes acquiring data for each parameter provided from each of a light source device which generates pulse light and an exposure apparatus which performs exposure on a wafer with the pulse light output from the light source device, and time data associated with the data; performing classification, based on the acquired data and time data, for each record of the data associated with same time data for distinguishing whether being data during exposure in which the wafer is irradiated with the pulse light or being data during non-exposure other than during the exposure; associating attribute information indicating an attribute according to the classification with each of the records; causing a storage device to store the data and the time data associated with the attribute information; and generating a chart using data read from the storage device.

A semiconductor manufacturing system according to another aspect of the present disclosure includes a light source device which generates pulse light, an exposure apparatus which performs exposure on a wafer with the pulse light output from the light source device, and an information processing device. Here, the information processing device includes a processor and a storage device. Further, the processor is configured to acquire data for each parameter provided from each of a light source device which generates pulse light and an exposure apparatus which performs exposure on a wafer with the pulse light output from the light source device, and time data associated with the data; to perform classification, based on the acquired data and time data, for each record of the data associated with same time data for distinguishing whether being data during exposure in which the wafer is irradiated with the pulse light or being data during non-exposure other than during the exposure; to associate attribute information indicating an attribute according to the classification with each of the records; to cause the storage device to store the data and the time data associated with the attribute information; and to generate a chart using data read from the storage device.

### BRIEF DESCRIPTION OF THE DRAWINGS

Embodiments of the present disclosure will be described below merely as examples with reference to the accompanying drawings.

FIG. 1 schematically shows a configuration example of a laser device management system according to a comparative example.

FIG. 2 schematically shows an example of the output timing of pulse laser light output from a laser device by burst operation.

FIG. 3 schematically shows an overview of scan exposure.

FIG. 4 is a flowchart showing an example of a flow of data writing control to a storage unit of an information processing device by a wafer data collection control unit.

FIG. 5 schematically shows an example of data stored in the storage unit of the information processing device.

FIG. 6 schematically shows an example of data stored in the storage unit of the information processing device.

FIG. 7 schematically shows a configuration example of a semiconductor manufacturing system according to the comparative example.

FIG. 8 is a flowchart showing an example of a main flow of processing by the information processing device.

FIG. 9 is a flowchart showing an example of a sub-flow applied to the process of step S202 in the flowchart of FIG. 8.

FIG. 10 is a flowchart showing an example of a sub-flow applied to the process of step S203 in the flowchart of FIG. 8.

FIG. 11 schematically shows an example of a mapped image.

FIG. 12 is a flowchart showing another example of the main flow of processing by the information processing device.

FIG. 13 shows a display example of a timeline chart of parameters of the laser device obtained by the information processing device.

FIG. 14 schematically shows a configuration example of the semiconductor manufacturing system including a chart display device according to a first embodiment.

FIG. 15 is a block diagram schematically showing the function of the chart display device.

FIG. 16 is a flowchart showing an example of the main flow of processing by the information processing device.

FIG. 17 is a flowchart showing an example of a sub-flow applied to the process of step S302 in the flowchart of FIG. 16.

FIG. 18 is a flowchart showing an example of a sub-flow applied to the process of step S304 in the flowchart of FIG. 16.

FIG. 19 is a flowchart showing an example of a sub-flow applied to the process of step S305 in the flowchart of FIG. 16.

FIG. 20 shows an example of a table including exposure/non-exposure information generated by the chart display device.

FIG. 21 schematically shows a configuration example of the semiconductor manufacturing system including a timeline chart display device according to a second embodiment.

FIG. 22 is a block diagram schematically showing the function of the timeline chart display device.

FIG. 23 is a flowchart showing an example of the main flow of processing by the timeline chart display device.

FIG. 24 is a flowchart showing an example of a sub-flow applied to the process of step S306 in the flowchart of FIG. 23.

FIG. 25 is a flowchart showing an example of a sub-flow applied to the process of step S308 in the flowchart of FIG. 23.

FIG. 26 is a display example of a timeline chart.

FIG. 27 shows an example of a dayline chart obtained by separately aggregating the number of pulses during exposure and the number of pulses during non-exposure.

FIG. 28 shows another example of a dayline chart obtained by separately aggregating the number of pulses during exposure and the number of pulses during non-exposure.

FIG. 29 is a block diagram schematically showing the function of the timeline chart display device according to a fifth embodiment.

FIG. 30 is a flowchart showing an example of a main flow of the timeline chart display device according to the fifth embodiment.

FIG. 31 is a display example of a chart displayed by the timeline chart display device according to the fifth embodiment.

FIG. 32 is a display example of a chart generated from the data only during non-exposure.

FIG. 33 is a display example in which a chart of data obtained by combining data during non-exposure and data during exposure and a chart of data only during non-exposure are simultaneously displayed.

### DESCRIPTION OF EMBODIMENTS

### <Contents>

1. Overview of laser device management system according to comparative example

1.1 Configuration

1.2 Operation
1.2.1 Energy control of laser device
1.2.2 Spectrum control of laser device
1.2.3 Beam measurement control of laser device
1.2.4 Gas control of laser device

1.3 Example of exposure operation by exposure apparatus

1.4 Example of wafer data collection control

1.5 Description of semiconductor manufacturing system according to comparative example
1.5.1 Configuration
1.5.2 Operation

1.6 Others

1.7 Problem

### 2. First Embodiment

2.1 Configuration

2.2 Operation

2.3 Example of table including exposure/non-exposure information

2.4 Effect

2.5 Modification

### 3. Second Embodiment

3.1 Configuration

3.2 Operation

3.3 Display example of timeline chart

3.4 Effect

### 4. Third Embodiment

4.1 Configuration

4.2 Operation

4.3 Effect

### 5. Fourth Embodiment

5.1 Configuration

5.2 Operation

5.3 Effect

### 6. Fifth Embodiment

6.1 Configuration

6.2 Operation

6.3 Display example of timeline chart and wafer mapped chart

6.4 Display example of chart generated using data during non-exposure

6.5 Effect

7. Laser oscillation during non-exposure

### 8. Others

Hereinafter, embodiments of the present disclosure will be described in detail with reference to the drawings. The embodiments described below show some examples of the present disclosure and do not limit the contents of the present disclosure. Also, all configurations and operation described in the embodiments are not necessarily essential as configurations and operation of the present disclosure. Here, the same components are denoted by the same reference numerals, and duplicate description thereof is omitted.

### 1. Overview of Laser Device Management System According to Comparative Example

### 1.1 Configuration

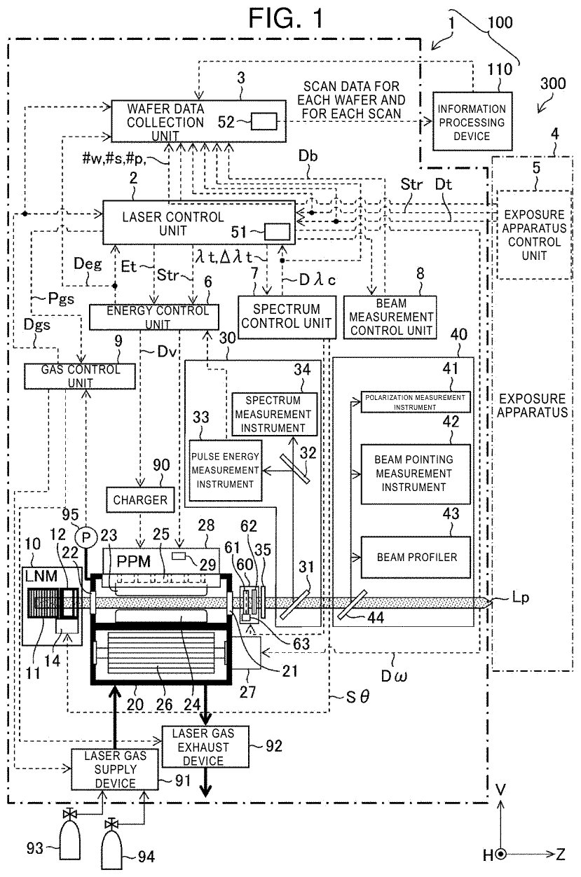

FIG. 1 schematically shows a configuration example of a laser device management system according to a comparative example. The comparative example of the present disclosure is an example recognized by the applicant as known only by the applicant, and is not a publicly known example admitted by the applicant. In the comparative example and the embodiments described below, an example of a laser device 1 is shown as a device for supplying pulse light to an exposure apparatus 4, but the present invention is not limited to this example. The device for supplying pulse light to the exposure apparatus 4 may be, for example, an EUV light source device for generating extreme ultraviolet (EUV) light. In the present specification, a device for supplying pulse light to the exposure apparatus 4 is defined as a light source device.

In the present specification, the optical path axis direction of laser light is the Z direction. The two directions substantially perpendicular to the Z direction may be the H direction and the V direction. The H direction is a direction substantially perpendicular to the paper surface of FIG. 1.

A laser device management system 100 is applied to a semiconductor manufacturing system 300, and collects data of various parameters of the laser device 1 to manage performance of the laser device 1. The laser device management system 100 includes the laser device 1 and an information processing device 110. The laser device 1 is a light source device for outputting pulse laser light Lp as pulse light. The laser device 1 performs laser oscillation, and outputs the pulse laser light Lp toward the exposure apparatus 4.

The information processing device 110 includes a storage unit and a processor that collects various data from a plurality of devices including the laser device 1 and the exposure apparatus 4 and that performs processing such as organizing and analysis of the data. The term “analysis” includes the concept of “data investigation.” The storage unit is configured using a computer-readable medium such as a semiconductor memory. The information processing device 110 may be, for example, a terminal device such as a personal computer (PC) operated by a laser manufacturer that is a manufacturer of the laser device 1. The information processing device 110 may be a server connected to a plurality of devices including the laser device 1 via a network.

The laser device 1 is a line narrowing gas laser device and includes a laser chamber 20, a line narrowing module (LNM) 10, an output coupling mirror (OC) 35, a spectral width varying unit 60, a monitor module (MM) 30, and a beam measurement instrument (BPM) 40. Further, the laser device 1 includes a charger 90, a laser gas supply device 91, a laser gas exhaust device 92, a laser control unit 2, an energy control unit 6, a spectrum control unit 7, a beam measurement control unit 8, a gas control unit 9, and a wafer data collection control unit 3.

The laser chamber 20 includes windows 21, 22, a pair of electrodes 23, 24, an electrically insulating member 25, a cross flow fan (CFF) 26, a motor 27, and a pulse power module (PPM) 28. The electrically insulating member 25 may be, for example, alumina ceramics. The motor 27 is a power source of the cross flow fan 26. The pulse power module 28 includes a switch 29 and a charging capacitor (not shown) and is connected to the electrode 23 via a feedthrough of the electrically insulating member 25. The electrode 24 is connected to the grounded laser chamber 20.

The line narrowing module 10 and the output coupling mirror 35 configure an optical resonator. The laser chamber 20 is arranged so that a discharge region of the pair of electrodes 23, 24 is arranged on the optical path of the optical resonator. The output coupling mirror 35 is coated with a multilayer film that reflects a part of the laser light generated in the laser chamber 20 and transmits another part thereof.

The line narrowing module 10 includes a grating 11, a prism 12, and a rotation stage 14 for rotating the prism 12. The prism 12 is arranged so that the beam of the laser light output from the laser chamber 20 is expanded by the prism 12 and is incident on the grating 11 at a predetermined angle.

The rotation stage 14 is arranged such that the incident angle of the beam on the grating 11 changes when the prism 12 is rotated. The grating 11 is arranged in the Littrow arrangement so that the incident angle and the diffraction angle of the beam are the same.

The charger 90 receives charge voltage data Dv from the energy control unit 6 and charges the charging capacitor of the pulse power module 28. A signal line for transmitting the charge voltage data Dv indicating a charge voltage V to the charger 90 is provided between the energy control unit 6 and the charger 90. The charge voltage V is a voltage for charging the charging capacitor. The charge voltage V is controlled based on a pulse energy E measured by a pulse energy measurement instrument 33.

A signal line for transmitting data of target pulse energy Et for performing energy control to the energy control unit 6 is provided between the laser control unit 2 and the energy control unit 6. Further, a signal line for transmitting a light emission trigger signal Str to the energy control unit 6 is provided between the laser control unit 2 and the energy control unit 6.

A signal line for transmitting data of a target wavelength Eλt and a target spectral line width Δλ for performing spectrum control to the spectrum control unit 7 is provided between the laser control unit 2 and the spectrum control unit 7.

A signal line for transmitting the light emission trigger signal Str to the beam measurement instrument 40 is provided between the laser control unit 2 and the beam measurement instrument 40.

A signal line for transmitting rotation speed data Dω for controlling rotation speed ω of the cross flow fan 26 to the motor 27 is provided between the laser control unit 2 and the motor 27 of the laser chamber 20.

The laser control unit 2 includes a storage unit 51. Various types of data are stored in the storage unit 51. The laser control unit 2 is communicably connected to the exposure apparatus control unit 5 of the exposure apparatus 4. The exposure apparatus control unit 5 controls the operation of the exposure apparatus 4. The light emission trigger signal Str output from the exposure apparatus control unit 5 is input to the laser control unit 2. The light emission trigger signal Str is input to the energy control unit 6 via the laser control unit 2. The energy control unit 6 and the pulse power module 28 are electrically connected so that the switch 29 is turned on and off in synchronization with the light emission trigger signal Str.

The monitor module 30 includes beam splitters 31, 32, the pulse energy measurement instrument 33, and the spectrum measurement instrument 34. The beam splitter 31 is arranged on the optical path of the pulse laser light Lp output from the output coupling mirror 35 so that the reflection light of the beam splitter 31 is incident on the beam splitter 32. The beam splitter 32 is arranged on the optical path of the pulse laser light Lp reflected by the beam splitter 31. The beam splitter 32 is arranged so that the reflection light of the beam splitter 32 enters the pulse energy measurement instrument 33 and the transmission light of the beam splitter 32 enters the spectrum measurement instrument 34.

The pulse energy measurement instrument 33 includes a light concentrating lens (not shown) and an optical sensor (not shown). The optical sensor is a fast response photodiode that is resistant to ultraviolet light.

The energy control unit 6 transmits the charge voltage data Dv to the charger 90 and controls the voltage of charging the charging capacitor of the pulse power module 28, based on the pulse energy detected by the pulse energy measurement instrument 33. A signal line for transmitting energy control related data Deg based on the measurement result by the pulse energy measurement instrument 33 to the laser control unit 2 and the wafer data collection control unit 3 is provided respectively between the energy control unit 6 and the laser control unit 2 and between the energy control unit 6 and the wafer data collection control unit 3.

The spectrum measurement instrument 34 is a spectrometer including an etalon (not shown) and an image sensor (not shown). The spectrum measurement instrument 34 may be, for example, a monitor etalon spectrometer including a monitor etalon, a light concentrating lens, and an image sensor, and configured to measure, by the image sensor, interference fringes generated on the focal plane by the light concentrating lens through the monitor etalon.

The spectrum control unit 7 controls the rotation stage 14 of the line narrowing module 10 based on the wavelength detected by the spectrum measurement instrument 34. A signal line for transmitting a stage angle control signal Sθ for controlling a rotation stage angle θ of the rotation stage 14 to the rotation stage 14 is provided between the spectrum control unit 7 and the rotation stage 14 of the line narrowing module 10. The rotation stage angle θ of the rotation stage 14 is controlled based on the wavelength λ detected by the spectrum measurement instrument 34.

The spectral width varying unit 60 is arranged on the optical path between the laser chamber 20 and the output coupling mirror 35. The spectral width varying unit 60 includes a cylindrical concave lens 61, a cylindrical convex lens 62, and a linear stage 63. As a modification of the spectral width varying unit 60, one surface of the cylindrical convex lens 62 located farthest from the laser chamber 20 may be a flat surface, and a partial reflection film may be coated on the flat surface to also function as an output coupling mirror. In this case, the output coupling mirror 35 is not arranged.

The cylindrical concave lens 61 and the cylindrical convex lens 62 are arranged on the optical path between the laser chamber 20 and the output coupling mirror 35. The lens distance between the cylindrical concave lens 61 and the cylindrical convex lens 62 can be changed by the linear stage 63.

A signal line for transmitting a stage position control signal for controlling the stage position of the linear stage 63 to the linear stage 63 is provided between the spectrum control unit 7 and the linear stage 63.

Further, a signal line for transmitting spectrum control related data Dλc based on the measurement result by the spectrum measurement instrument 34 to the laser control unit 2 and the wafer data collection control unit 3 is provided respectively between the spectrum control unit 7 and the laser control unit 2 and between the spectrum control unit 7 and the wafer data collection control unit 3.

The beam measurement instrument 40 includes a polarization measurement instrument 41, a beam pointing measurement instrument 42, a beam profiler 43, and a beam splitter 44. The beam splitter 44 is arranged on the optical path of the pulse laser light Lp output from the output coupling mirror 35. The reflection light of the beam splitter 44 is guided to each of the polarization measurement instrument 41, the beam pointing measurement instrument 42, and the beam profiler 43.

The polarization measurement instrument 41 measures the polarization degree of the laser light. The beam pointing measurement instrument 42 measures the beam pointing of the laser light. The beam profiler 43 measures the beam profile of the laser light.

The beam measurement control unit 8 calculates the beam measurement related data db based on image data and the like measured by the beam measurement instrument 40. A signal line for transmitting the beam measurement related data db to the laser control unit 2 and the wafer data collection control unit 3 is provided respectively between the beam measurement control unit 8 and the laser control unit 2 and between the beam measurement control unit 8 and the wafer data collection control unit 3.

The laser gas supply device 91 is configured to be capable of supplying a buffer gas and a gas containing fluorine into the laser chamber 20, respectively, as a laser gas based on a control signal from the gas control unit 9. The buffer gas is, for example, an Ar+Ne mixed gas. The gas containing fluorine is, for example, an Ar+Ne+F₂ mixed gas. The laser gas supply device 91 is connected to a gas cylinder 93 for supplying an Ar+Ne mixed gas as the buffer gas and a gas cylinder 94 for supplying an Ar+Ne+F₂ mixed gas as the gas containing fluorine. The laser gas supply device 91 includes a valve for controlling the supply of the Ar+Ne mixed gas from the gas cylinder 93, and a valve for controlling the supply of the Ar+Ne+F₂ mixed gas from the gas cylinder 94.

A signal line for transmitting gas control related data Dgs to the laser control unit 2 is provided between the gas control unit 9 and the laser control unit 2.

The laser gas exhaust device 92 is configured to be capable of exhausting the laser gas in the laser chamber 20 due to a control signal from the gas control unit 9. The laser gas exhaust device 92 includes a valve for controlling the exhaust, an exhaust pump, and a halogen filter for trapping the F₂ gas in the exhaust gas.

The wafer data collection control unit 3 is connected to the laser control unit 2, and collects data of various parameters via the laser control unit 2. The wafer data collection control unit 3 includes a storage unit 52. The storage unit 52 is configured using a computer-readable medium such as a semiconductor memory. The storage unit 52 stores data of various parameters for each wafer, for each scan, and for each pulse. The wafer data collection control unit 3 is connected to the information processing device 110. The data stored in the storage unit 52 can be referred to from the information processing device 110. The information processing device 110 can acquire the data stored in the storage unit 52 from the wafer data collection control unit 3.

The wafer data collection control unit 3 is configured to be capable of recognizing wafer exposure related information in the exposure apparatus 4 by receiving the light emission trigger signal Str from the exposure apparatus control unit 5 via the laser control unit 2 and measuring the trigger time interval. The wafer exposure related information includes a wafer number #w as wafer identification information, a scan number #s as scan identification information, and a pulse number #p as pulse identification information. The wafer number #w is associated with the wafer identification information (wafer ID). The wafer number may be understood to correspond to the wafer ID. The scan number may be information for identifying the position of the scan region in the wafer.

The wafer data collection control unit 3 is configured to be capable of storing, in the storage unit 52, the data of various parameters obtained through the laser control unit 2 with calculation processing performed thereon to be associated with the wafer exposure related information. That is, the wafer data collection control unit 3 organizes the data by linking the wafer exposure related information in the exposure apparatus 4 and the laser control related information in the laser device 1, and stores the data in the storage unit 52. The term “linking” is synonymous with “associating.” The data linked with the wafer exposure related information is the data obtained during exposure in which the wafer is irradiated with the pulse light. The term “during exposure” includes the concept of during exposure period (at the time of exposure).

The wafer data collection control unit 3 functions as a data buffer dedicated for data collection, and collects and holds data for each wafer, for each scan, and for each pulse. The data of the laser control related information linked with the wafer exposure related information includes at least one of various types of control related data, such as the energy control related data Deg, the spectrum control related data Dλc, the gas control related data Dgs, and the beam measurement related data Db.

The wafer data collection control unit 3 may also collect data related to the status of the laser device 1 during non-exposure other than the time of wafer exposure or the like. The term “during non-exposure” includes the concept of non-exposure period (at the time of non-exposure). The data storage period in the storage unit 52 may be set and changed by the information processing device 110. A signal line for transmitting a setting signal for setting such as the setting of the data storage period in the storage unit 52 to the wafer data collection control unit 3 is provided between the information processing device 110 and the wafer data collection control unit 3.

A signal line for transmitting data of the wafer exposure related information including the wafer number #w, the scan number #s, and the pulse number #p to the laser control unit 2 is provided between the exposure apparatus control unit 5 and the laser control unit 2. A signal line for the wafer data collection control unit 3 to receive the wafer exposure related information via the laser control unit 2 is provided between the laser control unit 2 and the wafer data collection control unit 3.

A signal line for transmitting the gas control related data Dgs to the wafer data collection control unit 3 is provided between the gas control unit 9 and the wafer data collection control unit 3.

The laser control unit 2 is communicably connected to the wafer data collection control unit 3, the energy control unit 6, the spectrum control unit 7, the beam measurement control unit 8, the gas control unit 9, and the exposure apparatus control unit 5. The exposure apparatus control unit 5 is a processor that controls the exposure apparatus 4.

Each of the laser control unit 2, the wafer data collection control unit 3, the energy control unit 6, the spectrum control unit 7, the beam measurement control unit 8, the gas control unit 9, the exposure apparatus control unit 5, and other control units are configured using at least one processor. For example, each of these control units may be realized by a combination of hardware and software of a computer including a processor. Software is synonymous with programs. The computer may include a central processing unit (CPU) and a memory. The CPU is an example of the processor. A programmable controller is included in the concept of the computer.

A part of the processing functions of the computer may be realized using an integrated circuit such as a field programmable gate array (FPGA) or an application specific integrated circuit (ASIC).

The functions of a plurality of control units can also be realized by one computer. Further, in the present disclosure, the devices including the processor may be connected to each other via a communication network such as a local area network or an Internet line. In a distributed computing environment, program units may be stored in both local and remote memory storage devices.

### 1.2 Operation

### 1.2.1 Energy Control of Laser Device

The laser control unit 2 receives various types of target data and the light emission trigger signal Str from the exposure apparatus control unit 5. The target data includes, for example, target pulse energy Et, a target wavelength λt, and a target spectral line width Δλt.

The laser control unit 2 transmits the target pulse energy Et and the light emission trigger signal Str to the energy control unit 6. The energy control unit 6 transmits the charge voltage data Dv to the charger 90, and transmits an ON signal to the switch 29 of the pulse power module 28 in synchronization with the light emission trigger signal Str. When a high voltage is applied between the pair of electrodes 23, 24 from the pulse power module 28, dielectric breakdown occurs in the laser gas in the laser chamber 20, and discharge occurs. As a result, the laser gas is excited and laser oscillation occurs by the optical resonator configured of the line narrowing module 10 and the output coupling mirror 35.

A part of the beam of the pulse laser light Lp output from the output coupling mirror 35 is sampled by the beam splitters 31, 32 and enters the pulse energy measurement instrument 33.

The pulse energy measurement instrument 33 measures the pulse energy E of the pulse laser light Lp output from the laser device 1.

The energy control unit 6 calculates the charge voltage V of the next pulse based on the difference ΔE between the pulse energy E and the target pulse energy Et, and transmits the charge voltage data Dv to the charger 90. As a result, the pulse energy E of the pulse laser light Lp output from the laser device 1 approaches the target pulse energy Et.

The energy control related data Deg is transmitted from the energy control unit 6 to the laser control unit 2 and the wafer data collection control unit 3. The energy control related data Deg includes, for example, data such as the target pulse energy Et, the measured pulse energy E, and the charge voltage V.

### 1.2.2 Spectrum Control of Laser Device

The laser control unit 2 transmits the target wavelength λ t, the target spectral line width Δλt, and the light emission trigger signal Str to the spectrum control unit 7.

A part of the beam of the pulse laser light Lp output from the output coupling mirror 35 is sampled by the beam splitters 31, 32 and enters the spectrum measurement instrument 34. The spectrum measurement instrument 34 measures the wavelength λ and the spectral line width Δλ of the pulse laser light Lp.

The spectrum control unit 7 transmits a signal for controlling the rotation stage angle θ of the rotation stage 14 of the line narrowing module 10, based on a difference δλ between the wavelength λ measured by the spectrum measurement instrument 34 and the target wavelength λt, so that δλ approaches 0. As a result, the wavelength of the pulse laser light Lp output from the laser device 1 approaches the target wavelength λt.

Further, the spectrum control unit 7 transmits a signal for controlling the linear stage 63 of the spectral width varying unit 60, based on a difference ΔΔλ between the measured spectral line width Δλ and the target spectral line width Δλt, so that ΔΔλ approaches 0. As a result, the spectral line width Δλ of the output pulse laser light Lp approaches the target spectral line width Δλt.

The spectrum control related data Dλc is transmitted from the spectrum control unit 7 to the laser control unit 2 and the wafer data collection control unit 3. The spectrum control related data Dλc includes, for example, data of at least one parameter of the target wavelength λt, the measured wavelength λ, and the spectral line width Δλ. Preferably, data of a plurality of parameters is included.

### 1.2.3 Beam Measurement Control of Laser Device

The beam measurement control unit 8 analyzes the image data obtained from image sensors of the polarization measurement instrument 41, the beam pointing measurement instrument 42, and the beam profiler 43. The beam measurement related data db includes, for example, data of at least one parameter of the beam size, the beam position, the beam divergence, the beam pointing, and the polarization degree. Preferably, data of a plurality of parameters is included. The beam measurement related data db is transmitted from the beam measurement control unit 8 to the laser control unit 2 and the wafer data collection control unit 3.

### 1.2.4 Gas Control of Laser Device

The laser control unit 2 transmits data of gas control parameters to the gas control unit 9. The gas control parameters include, for example, the charge voltage V, a maximum charge voltage Vmax, a minimum charge voltage Vmin, and the like.

The gas control unit 9 performs gas pressure control. The gas pressure control is a gas control method utilizing the following properties. When the laser gas pressure increases, the dielectric breakdown voltage increases and the pulse energy of the output pulse laser light Lp increases. Conversely, when the laser gas pressure decreases, the dielectric breakdown voltage decreases and the pulse energy of the output pulse laser light Lp decreases.

The gas control unit 9 measures the gas pressure (chamber gas pressure) P in the laser chamber 20 using a pressure sensor 95. The data of the chamber gas pressure P is transmitted to the laser control unit 2. When the charge voltage V becomes equal to or higher than Vmax, the gas control unit 9 controls the laser gas supply device 91 so that the laser gas pressure increases by ΔP by supplying the Ar+Ne mixed gas. Conversely, when the charge voltage V becomes equal to or lower than Vmin, the gas control unit 9 controls the laser gas exhaust device 92 so that the laser gas pressure decreases by ΔP by exhausting the Ar+Ne mixed gas.

Further, the gas control unit 9 performs partial gas exchange control. The partial gas exchange control is, for example, control in which a predetermined amount of the Ar+Ne mixed gas and the Ar+Ne+F₂ mixed gas are injected at a constant cycle, and gas is exhausted by the total amount of the injected gas. The gas control unit 9 replenishes the amount of fluorine decreased due to the discharge, and performs gas exchange of a part of the laser gas in the laser chamber 20.

The gas control related data Dgs is transmitted from the gas control unit 9 to the laser control unit 2 and the wafer data collection control unit 3. The gas control related data Dgs includes, for example, data such as the chamber gas pressure P.

The laser control unit 2 stores various types of data in the storage unit 51 periodically, for example, at a predetermined time period or for each predetermined number of shots. The various types of data herein include, for example, at least one of the energy control related data Deg, the spectrum control related data Dλc, the gas control related data Dgs, and the beam measurement related data Db.

### 1.3 Example of Exposure Operation by Exposure Apparatus

The exposure apparatus 4 is an apparatus that performs wafer exposure. The wafer exposure includes performing scan exposure. The “scan exposure” is a method of exposing an exposure region of a wafer while scanning with the pulse laser light Lp. The laser device 1 performs burst operation in accordance with the wafer exposure in the exposure apparatus 4. The “burst operation” is operation in which a burst period in which the pulse laser light Lp narrowed in line width is continuously oscillated in accordance with the scan exposure and an oscillation pause period in which oscillation is paused are alternately repeated. Here, prior to describing the configuration of the laser device management system 100, an overview of the burst operation and the wafer exposure will be described.

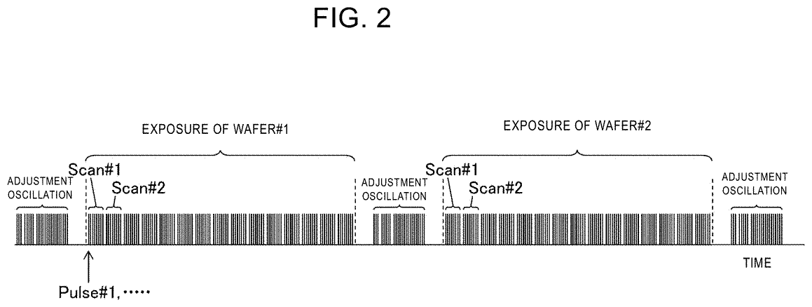

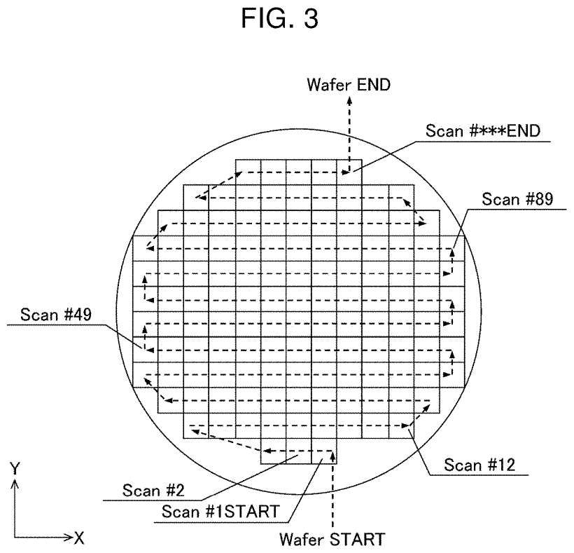

FIG. 2 schematically shows an example of the output timing of the pulse laser light Lp output from the laser device 1 by the burst operation. FIG. 3 schematically shows an overview of the scan exposure.

In FIG. 2, one vertical line indicates one pulse of the pulse laser light Lp. As shown in FIG. 2, the laser device 1 first performs adjustment oscillation, and after a predetermined time interval, performs the burst operation for the first wafer exposure (Wafer #1).

The adjustment oscillation is oscillation in which the pulse laser light Lp for adjustment is output while irradiation of the pulse laser light Lp to the wafer is not performed. The adjustment oscillation is performed under predetermined conditions until the laser is stabilized in a state in which exposure can be performed, and is performed before lot production of wafers. The pulse laser light Lp is output at a predetermined frequency of, for example, several hundred to several thousand Hz. During the wafer exposure, it is general to perform the burst operation in which the burst period and the oscillation pause period are repeated. The burst operation is also performed in the adjustment oscillation.

In FIG. 2, a section in which pulses are densely present is the burst period in which the pulse laser light Lp is continuously output for a predetermined period. Further, in FIG. 2, the section in which no pulse is present is the oscillation pause period. In the adjustment oscillation, the length of each continuous output period of pulses need not to be constant, and each continuous output operation may be performed with different length of the continuous output period for adjustment. After performing the adjustment oscillation, the first wafer exposure (Wafer #1) is performed in the exposure apparatus 4 after a relatively large time interval.

As shown in FIG. 3, the wafer exposure is performed by dividing the wafer into a plurality of predetermined exposure regions and performing scan exposure on each exposure region during a period between the start (Wafer START) and the end (Wafer END) of the wafer exposure. That is, in the wafer exposure, steps of exposing a first predetermined exposure region of the wafer by a first scan exposure (Scan #1) and then exposing a second predetermined exposure region by a second scan exposure (Scan #2) are repeated. During one scan exposure, a plurality of pulses of the pulse laser light Lp (Pulse #1, Pulse #2, . . . ) can be continuously output from the laser device 1. When the scan exposure (Scan #1) of the first predetermined exposure region is completed, the scan exposure (Scan #2) of the second predetermined exposure region is performed after a predetermined time interval. This scan exposure is sequentially repeated, and when the scan exposure of the entire exposure region of the first wafer is completed, adjustment oscillation is performed again, and then the wafer exposure (Wafer #2) of a second wafer is performed.

Step-and-scan exposure is performed in the order of the broken line arrows shown in FIG. 3 (Wafer START→Scan #1→Scan #2→, . . . , →Scan #126→Wafer END).

The wafer data collection control unit 3 receives the wafer number, the scan number, and the light emission trigger signal Str of an exposure pattern as shown in FIG. 2 from the exposure apparatus control unit 5, and recognizes the Wafer #number and the Scan #number for each pulse by measuring the trigger time interval.

### 1.4 Example of Wafer Data Collection Control

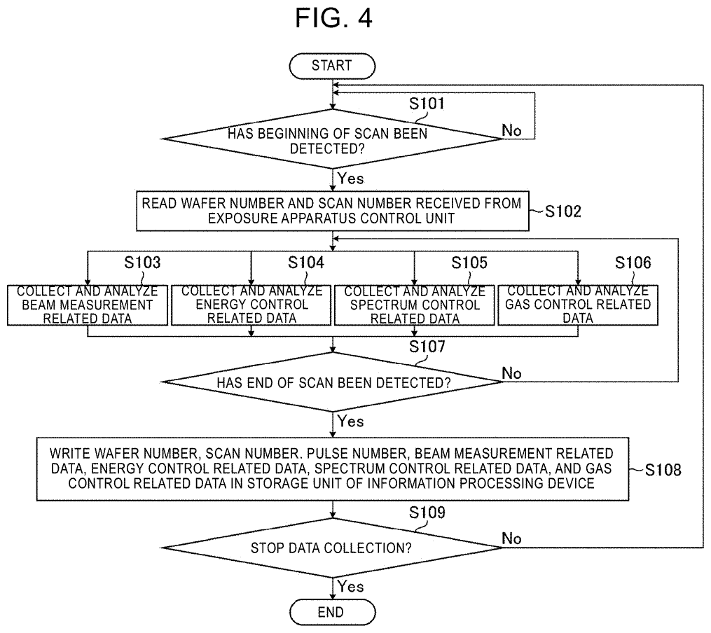

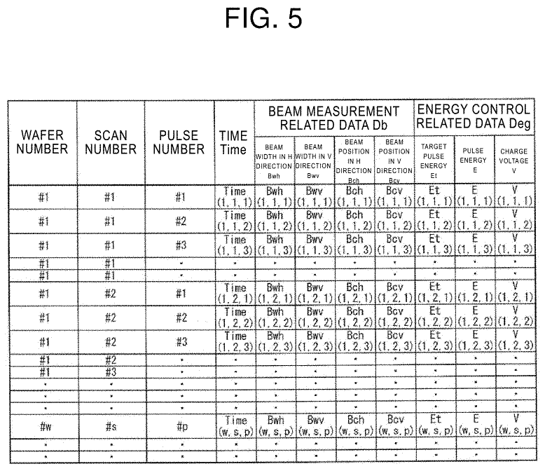

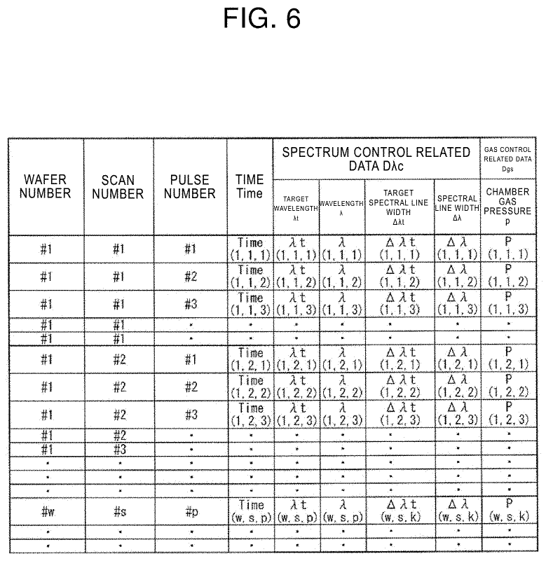

FIG. 4 is a flowchart showing an example of a flow of data writing control to the storage unit of the information processing device 110 by the wafer data collection control unit 3. FIGS. 5 and 6 schematically show an example of data stored in the storage unit of the information processing device 110.

The wafer data collection control unit 3 detects the beginning of the burst period for each wafer exposure as shown in FIG. 2. The detection of the beginning of the burst period is performed by determining whether or not the beginning of the scan has been detected (step S101).

For example, the wafer data collection control unit 3 may detect the beginning of the scan by receiving the first scan number Scan #1 from the exposure apparatus control unit 5 via the laser control unit 2. Further, the wafer data collection control unit 3 may detect the beginning of the burst period by measuring the oscillation pause period and detecting the first pulse after the oscillation pause period of a predetermined period or more, for example, 0.1 s or more.

When it is determined that the beginning of the scan has not been detected (when the determination result of step S101 is NO), the wafer data collection control unit 3 repeats the process of step S101.

On the other hand, when it is determined that the beginning of the scan has been detected (when the determination result of step S101 is YES), the wafer data collection control unit 3 next reads the wafer number #w, the scan number #s, and the pulse number #p received from the exposure apparatus control unit 5 via the laser control unit 2 (step S102).

Next, the wafer data collection control unit 3 performs at least one of the processes of steps S103 to S106. The wafer data collection control unit 3 collects and analyzes the beam measurement related data db as the process of step S103. The wafer data collection control unit 3 collects and analyzes the energy control related data Deg as the process of step S104. The wafer data collection control unit 3 collects and analyzes the spectrum control related data Dλc as the process of step S105. The wafer data collection control unit 3 collects and analyzes the gas control related data Dgs as the process of step S106.

Next, the wafer data collection control unit 3 determines whether or not the end of the scan has been detected (step S107). For example, the wafer data collection control unit 3 may detect the end of the scan when a valid scan number is not transmitted from the exposure apparatus control unit 5. Further, the wafer data collection control unit 3 may detect the end of the burst period, that is, the end of the scan by measuring the oscillation pause period and detecting the oscillation pause period of a predetermined period or more, for example, 0.1 s or more.

When it is determined that the end of the scan has not been detected (when the determination result of step S107 is NO), the processes of steps S103 to S107 are repeated.

On the other hand, when it is determined that the end of the scan has been detected (when the determination result of step S107 is YES), the wafer data collection control unit 3 writes the collected and analyzed data in the storage unit of the information processing device 110 (step S108).

Next, the wafer data collection control unit 3 determines whether or not to stop data collection (step S109). When it is determined that the data collection is not to be stopped (when the determination result of step S109 is NO), the wafer data collection control unit 3 returns to step S101. On the other hand, when it is determined that the data collection is to be stopped (when the determination result of step S109 is YES), the wafer data collection control unit 3 ends processing of the data collection.

FIGS. 5 and 6 schematically show an example of data written in the storage unit of the information processing device 110. The data collected and analyzed by the wafer data collection control unit 3 includes the wafer number #w, the scan number #s, and the pulse number #p. The data collected and analyzed by the wafer data collection control unit 3 includes, for each pulse, the beam measurement related data Db, the energy control related data Deg, the spectrum control related data Dλc, and the gas control related data Dgs.

As shown in FIGS. 5 and 6, for example, the beam measurement related data Db, the energy control related data Deg, the spectrum control related data Dλc, and the gas control related data Dgs are associated with the wafer number #w, the scan number #s, and the pulse number #p and written in the storage unit of the information processing device 110.

### 1.5 Description of Semiconductor Manufacturing System According to Comparative Example

### 1.5.1 Configuration

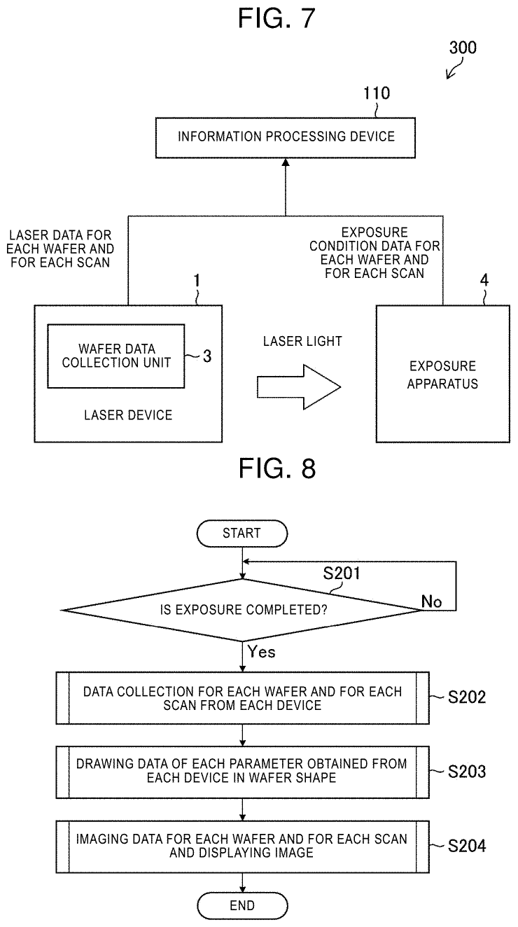

FIG. 7 schematically shows a configuration example of the semiconductor manufacturing system 300 according to the comparative example. The semiconductor manufacturing system 300 includes the laser device 1, the exposure apparatus 4, and the information processing device 110. The information processing device 110 is configured to receive data for each wafer and for each scan from the laser device 1 and the exposure apparatus 4. The information processing device 110 includes a storage unit (not shown). The information processing device 110 is connected to a display (not shown).

### 1.5.2 Operation

According to the flowchart of FIG. 4, the information processing device 110 receives laser data from the laser device 1 for each wafer and for each scan, and stores the received laser data in the storage unit. The laser data is data of, for example, pulse counts, the pulse energy E, the charge voltage V, the wavelength λ, the spectral line width Δλ, and the chamber gas pressure P for each wafer and for each scan.

The information processing device 110 can acquire various types of data via the wafer data collection control unit 3 of the laser device 1. Further, the information processing device 110 may directly acquire data from the exposure apparatus 4 or the like without via the wafer data collection control unit 3.

The information processing device 110 receives exposure condition data from the exposure apparatus 4 for each wafer and for each scan, and stores the received laser data in the storage unit. The exposure condition data includes, for example, an exposure pulse energy and a focus position Zf in the height direction of the wafer (a height position of the wafer surface).

The information processing device 110 may further receive the data of the measurement result from a wafer inspection apparatus (not shown) for each wafer and for each scan, and store the received data in the storage unit. The data of the measurement result obtained from the wafer inspection apparatus includes, for example, a number of defects, height distribution of the wafer surface, and line width distribution of a pattern.

The information processing device 110 may further receive the data of manufacturing conditions from another manufacturing apparatus (not shown) for each wafer and for each scan, and store the received data in the storage unit. “Another manufacturing apparatus” herein may be, for example, an apparatus for coating a wafer with a resist or a chemical vapor deposition (CVD) apparatus for forming a thin film. In the other manufacturing apparatus, the thickness of the resist or the thickness of the film may be measured and data of the thickness of the resist or the thickness of the thin film may be collected for each wafer and for each scan.

FIG. 8 is a flowchart showing an example of a main flow of processing by the information processing device 110. The processing shown in the flowchart of FIG. 8 is realized by a processor configuring the information processing device 110 executing an instruction of a program.

In step S201, the information processing device 110 determines whether or not exposure of the wafer is completed. When the exposure of the wafer is not completed (when the determination result of step S201 is NO), the information processing device 110 repeats step S201.

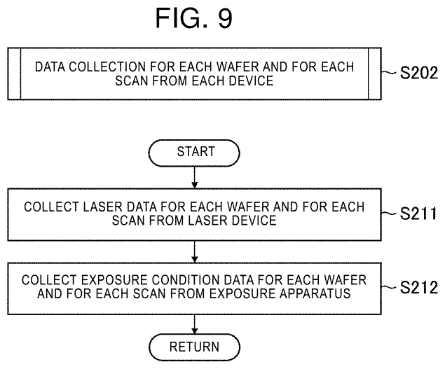

When the exposure of the wafer is completed, the information processing device 110 proceeds to step S202. In step S202, the information processing device 110 collects data for each wafer and for each scan from each device. The information processing device 110 collects laser data for each wafer and for each scan from the laser device 1 and data related to a recipe from the exposure apparatus 4. Details of step S202 will be described later with reference to FIG. 9.

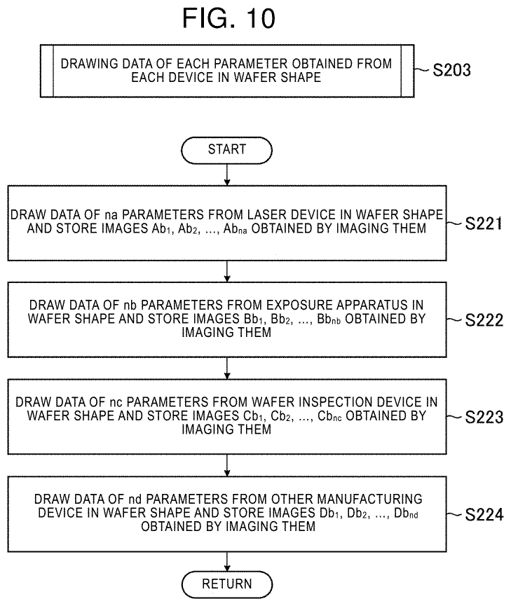

In step S203 after step S202, the information processing device 110 performs a process of drawing, in a wafer shape, the data of each parameter obtained from each device. That is, the information processing device 110 draws the data of parameters in the wafer shape using information of the position of the scan with respect to the wafer and the size of the exposure region from the collected information. Details of step S203 will be described later with reference to FIG. 10.

Then, the information processing device 110 performs a process of imaging the data for each wafer and for each scan from each device and displaying the image (step S204). The map drawn in the wafer shape in step S203 is imaged to facilitate management, displaying, and analysis. After step S204, the flowchart of FIG. 8 ends.

FIG. 9 is a flowchart showing an example of a sub-flow applied to the process of step S202 in the flowchart of FIG. 8. The information processing device 110 first collects the laser data for each wafer and for each scan from the laser device 1 (step S211). The laser data collected by the information processing device 110 in step S211 includes data of, for example, the beam measurement related data Db, the energy control related data Deg, the spectrum control related data Dλc, and the gas control related data Dgs for each wafer and for each scan.

Next, the information processing device 110 collects the exposure condition data for each wafer and for each scan from the exposure apparatus 4 (step S212). The exposure condition data includes, for example, the target pulse energy Et, the target wavelength λt, the target spectral line width Δλt, an exposure pulse energy Pex measured by the exposure apparatus 4, and the focus position Zf in the height direction of the wafer. Here, the order of the processes of step S211 and step S212 can be interchanged.

Although not shown in FIG. 9, in addition to steps S211, S212, the information processing device 110 may collect inspection data from the wafer inspection apparatus for each wafer and for each scan. The information processing device 110 may collect manufacturing data for each wafer and for each scan from the other manufacturing apparatus.

After data collection including steps S211, S212, the information processing device 110 ends the flowchart of FIG. 9 and returns to the main flow of FIG. 8.

FIG. 10 is a flowchart showing an example of a sub-flow applied to the process of step S203 in the flowchart of FIG. 8.

In step S221, the information processing device 110 draws data of na parameters from the laser device 1 in the wafer shape, and stores an image Ab₁, an image Ab₂, . . . , and an image Abₙₐ obtained by imaging them, respectively, in the storage unit.

In step S222, the information processing device 110 draws data of nb parameters from the exposure apparatus 4 in the wafer shape, and stores an image Bb₁, an image Bb₂, . . . , and an image Bb_{nb} obtained by imaging them, respectively, in the storage unit.

When data is acquired from the wafer inspection apparatus or the other manufacturing apparatus, the information processing device 110 further performs the processes of steps S223, S224. That is, in step S223, the information processing device 110 draws data of nc parameters from the wafer inspection apparatus in the wafer shape, and stores an image Cb₁, an image Cb₂, . . . , and an image Cb_{nc} obtained by imaging them, respectively, in the storage unit.

Next, in step S224, the information processing device 110 draws data of nd parameters from the other manufacturing apparatus in the wafer shape, and stores an image db₁, an image db₂, . . . , and an image db_{nd} obtained by imaging them, respectively, in the storage unit.

After step S224, the information processing device 110 ends the flowchart of FIG. 10 and returns to the main flow of FIG. 8. Here, the order of the processes of steps S221 to S224 can be interchanged.

The information processing device 110 visualizes and images the data of each of the plurality of parameters collected from the plurality of apparatuses in units of a predetermined area in the wafer, and generates a plurality of mapped images for each of the parameters of the plurality of apparatuses. Here, the predetermined area may be an exposure region (scan region) in which one scan exposure is performed by the exposure apparatus 4. Further, the predetermined area may be an area obtained by further dividing the area in which scan exposure is performed.

The information processing device 110 generates, for example, a mapped image in which the difference in data for each parameter is represented by shading. In this case, the information processing device 110 may set the target value of each parameter to the median value of the shades.

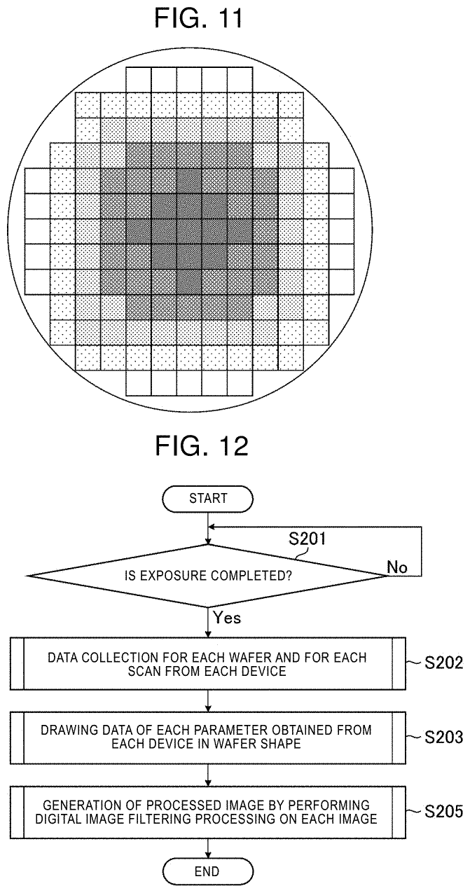

FIG. 11 schematically shows an example of the mapped image. The mapped image of FIG. 11 is an example in which data of any one parameter obtained when, for example, the first wafer exposure (Wafer #1) is performed is drawn in a wafer shape and imaged.

FIG. 12 is a flowchart showing another example of the main flow of processing by the information processing device 110. The information processing device 110 may execute the flowchart shown in FIG. 12 instead of the flowchart shown in FIG. 8 or in addition to the main flow shown in FIG. 8. Differences from FIG. 8 will be described.

The flowchart shown in FIG. 12 includes step S205 instead of step S204 in FIG. 8. In step S205, the information processing device 110 performs digital image filtering processing on each mapped image obtained in step S203 to generate processed images. As the digital image filter, for example, a median filter or an averaging filter may be used.

Digital filter processing is performed on each mapped image to capture the characteristics of each parameter.

The processed image generated in step S205 is stored in the storage unit of the information processing device 110. The processed image can be displayed on the display of the information processing device 110.

### 1.6 Others

In the configuration example of FIG. 1, an example of an ArF excimer laser is shown, but the present invention is not limited to this example, and may be applied to an excimer laser such as KrF, XeCl, or XeF. The laser gas may be generated by injecting a mixed gas of a rare gas and a buffer gas and a mixed gas of a rare gas, a buffer gas, and a halogen gas into the laser chamber 20 by a predetermined amount.

Further, in the configuration example of FIG. 1, an example of the laser device 1 of a single chamber system is shown, but the present invention is not limited to this example, and for example, a laser device including an amplifier in which another laser chamber and another optical resonator are arranged on the optical path between the output coupling mirror 35 and the monitor module 30 may be used.

### 1.7 Problem

In the exposure process in semiconductor manufacturing, improvement of quality and pursuit of accuracy are required. In order to improve the quality, it is necessary to repeat collecting and analyzing various types of data obtained from a plurality of apparatuses configuring the semiconductor manufacturing system and performing feedback to the manufacturing process.

The laser device 1 cannot distinguish whether the light emission trigger signal Str received from the exposure apparatus control unit 5 is a light emission command for wafer exposure or a light emission command for adjustment oscillation or the like other than wafer exposure. Therefore, it is difficult to determine whether the laser oscillation is oscillation during wafer exposure or during non-exposure such as adjustment oscillation, based only on the data of parameters related to the performance of the laser device 1, and it is difficult to accurately grasp the correlation between the parameters at the time of laser oscillation during exposure or non-exposure and the wafer quality.

The information processing device 110 according to the comparative example is configured to analyze the data of various parameters during wafer exposure in order to grasp the correlation between the parameters at the time of laser oscillation and the wafer quality. On the other hand, with respect to the data of the parameters during non-exposure such as adjustment oscillation, although the data is collected in the laser device 1, utilization of the data analysis and the like are not assumed, and the data is not organized and is not sufficiently utilized.

As described in FIGS. 5 and 6, in the laser device management system 100 according to the comparative example, only data during wafer exposure is organized as being linked with wafer exposure related information such as wafer numbers. Data during non-exposure not shown in FIGS. 5 and 6 are merely accumulated (stored) and are not organized as data to be analyzed.

The information processing device 110 according to the comparative example extracts only the data during exposure to the wafer and can only analyze the laser performance during exposure, so that it is difficult to perform fine analysis due to the difference between during exposure and during non-exposure. The data of the laser performance during exposure reflects the control by the recipe from the exposure apparatus 4 and includes a factor depending on the recipe. Therefore, it is effective for correlation analysis with the wafer quality, but not necessarily suitable for monitoring the aging degradation and the like of the laser device 1. That is, since the data during exposure varies depending on the exposure conditions of the wafer, it is difficult to compare and evaluate the performance due to aging deterioration of the laser device 1 itself from the data during exposure.

On the other hand, since the data related to the parameters during non-exposure includes those acquired under specific conditions independent of the exposure conditions of the wafer, it is expected that the performance of the laser device 1 independent of the recipe or the like can be evaluated by organizing and analyzing the data during non-exposure.

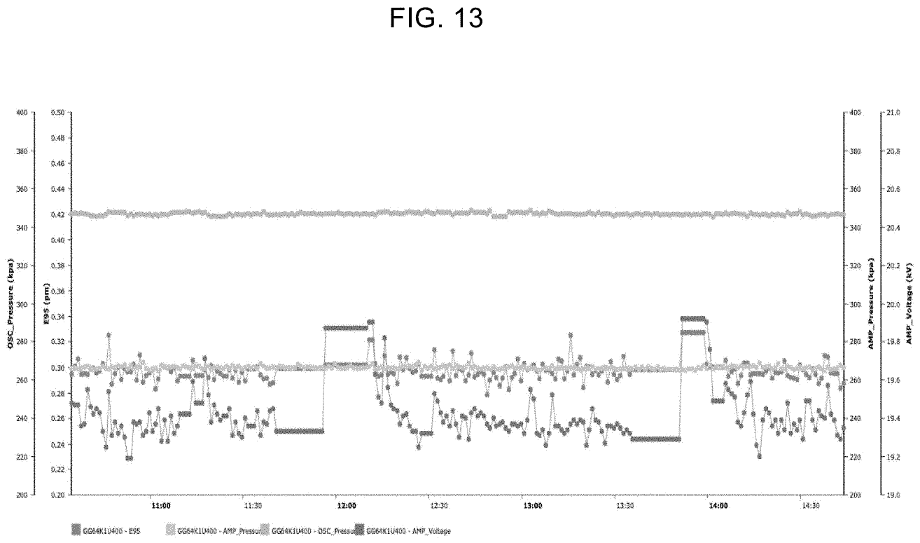

Furthermore, as another problem, when a timeline chart or the like is simply displayed as shown in FIG. 13 for data including data during exposure and data during non-exposure accumulated in time series with respect to a certain parameter, the period during exposure and the period during non-exposure cannot be clearly distinguished on the chart, and it is not possible to grasp whether the data is data during exposure or data during non-exposure.

FIG. 13 shows a display example of a timeline chart of parameters of the laser device 1 obtained by the information processing device 110. The horizontal axis represents time, and the vertical axis represents the value of each parameter. Here, a chart is exemplified showing, in timeline form, the transition of data of each of four parameters of the spectral line width of E95, the chamber gas pressure of the oscillator, the chamber gas pressure of the amplifier, and the charge voltage of the amplifier. Here, E95 refers to the spectral width at which 95% of the energy in the laser spectrum is concentrated.

The information processing device 110 can display a timeline chart as shown in FIG. 13 on the display for the data of each parameter acquired in time series. The chart display as shown in FIG. 13 is a hybrid chart of the data during wafer exposure and the data during non-exposure such as adjustment oscillation, and it is impossible to easily grasp whether the value of the parameter at a certain time is during exposure or during non-exposure.

### 2. First Embodiment

Next, a semiconductor manufacturing system 310 according to a first embodiment will be described. In the following, the same reference numerals are given to substantially the same components as those of the semiconductor manufacturing system 300 according to the comparative example, and description thereof will be appropriately omitted.

### 2.1 Configuration

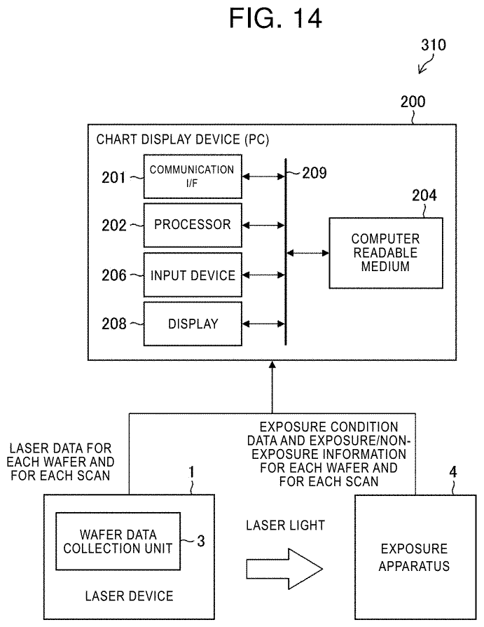

FIG. 14 schematically shows a configuration example of the semiconductor manufacturing system 310 including a chart display device 200 according to the first embodiment. The semiconductor manufacturing system 310 includes the chart display device 200 in place of the information processing device 110 according to the comparative example. The chart display device 200 may be a terminal device such as a personal computer or a server connected to a network. The chart display device 200 is an information processing device including a communication function for receiving data, for each parameter, related to various parameters provided from the laser device 1 and the exposure apparatus 4, a data processing function for processing the received data, and a display function for displaying information such as a processing result of the data. The chart display device 200 is an example of the “information processing device” in the present disclosure.

The chart display device 200 includes a communication interface 201, a processor 202, a computer readable medium 204, an input device 206, and a display 208. The processor 202 includes a CPU. The processor 202 may include one or more electronic circuits such as an ASIC and an FPGA in addition to the CPU. The processor 202 is connected to the communication interface 201, the computer readable medium 204, the input device 206, and the display 208 via a bus 209.

The computer readable medium 204 includes a memory that is the main storage device and a storage that is an auxiliary storage device. The computer readable medium 204 may be, for example, a semiconductor memory, a hard disk drive (HDD) device, a solid state drive (SSD) device, or a combination thereof. The program to be executed by the processor is stored in the computer readable medium 204. The computer readable medium 204 is an example of the “storage device” in the present disclosure.

The chart display device 200 is connected to the laser device 1 and the exposure apparatus 4 via the communication interface 201 and is configured to receive various types of data for each wafer, for each scan, and for each pulse from the laser device 1 and the exposure apparatus 4. The chart display device 200 may receive data transmitted from the exposure apparatus 4 via the laser device 1.

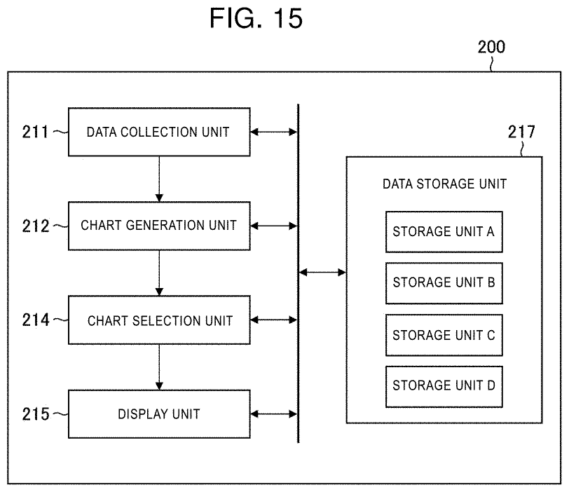

FIG. 15 is a block diagram schematically showing the function of the chart display device 200. The chart display device 200 includes a data collection unit 211, a chart generation unit 212, a chart selection unit 214, a display unit 215, and a data storage unit 217.

The data collection unit 211 acquires data for each parameter as an analysis target of each device from each of the plurality of devices including the laser device 1, the exposure apparatus 4, the wafer inspection apparatus, and the other manufacturing apparatus. The data collection unit 211 includes a communication interface 201 that receives data transmitted from the plurality of devices including the laser device 1 and the exposure apparatus 4. The data collection unit 211 may be configured to automatically acquire data of each parameter from the plurality of devices according to an instruction of the program.

The data collection unit 211 collects not only data during exposure for each wafer and for each scan, but also at the time of laser oscillation during a period other than exposure, that is, non-exposure such as adjustment oscillation and running-in operation. Time data indicating the time at which each data is generated is linked with the data of each parameter.

The wafer data collection control unit 3 of the laser device 1 accumulates data for each parameter in a pulse unit or in a scan unit in time series with the time data. The data collection unit 211 acquires data from the wafer data collection control unit 3. The data collection unit 211 may include a part or all of the processing functions of the wafer data collection control unit 3.

The data collection unit 211 can organize and manage the data arranged in chronological order based on the time data. The data collection unit 211 performs classification for distinguishing whether the data for each record linked with the same time data is data during exposure or data during non-exposure based on the time data, recipe data obtained from the exposure apparatus 4, and the like, and performs processing for linking, to each record, the wafer number and the scan number as exposure information or non-exposure information, which are attribute information corresponding to the classification. A part or all of the processing for linking the exposure/non-exposure information may be performed in the chart generation unit 212.

When there is a time difference between a built-in clock of the exposure apparatus 4 and a built-in clock of the laser device 1, it is possible to make the time coincide with each other by offsetting the time data according to the time difference with reference to either one of the time.

The chart generation unit 212 processes the collected data to generate various charts. The “chart” may have various forms such as a graph, a wafer shape mapped image, and a tabular list. A part or all of the processing functions of the data collection unit 211 and the chart generation unit 212 are realized by the processor 202 executing instructions of the program.

The data storage unit 217 stores data acquired via the data collection unit 211 and data of the charts generated by the chart generation unit 212. The data storage unit 217 is a non-transitory storage area of the computer readable medium 204 which is a tangible entity. The data storage unit 217 includes a plurality of storage units A, B, C, D. The storage unit A is a storage area for storing mapped images generated based on the respective parameters of the laser data obtained from the laser device 1, processed images obtained by performing digital image filtering processing on the mapped images, and the like. The storage unit B is a storage area for storing mapped images generated based on the respective parameters of the exposure condition data obtained from the exposure apparatus 4, processed images obtained by performing digital image filtering processing on the mapped images, and the like.

The storage unit C is a storage area for storing mapped images generated based on the respective parameters obtained from the wafer inspection apparatus, processed images obtained by performing digital image filtering processing on the mapped images, and the like. The storage unit D is a storage area for storing mapped images generated based on the respective parameters obtained from the other manufacturing apparatus, processed images obtained by performing digital image filtering processing on the mapped images, and the like.

The chart selection unit 214 receives user operation of selecting a chart desired by the user from a plurality of charts to be generated by the chart generation unit 212. The chart selection unit 214 includes at least one input device 206 of, for example, a keyboard, a mouse, a touch panel, a digitizer, and a voice input device. The chart selection unit 214 receives user operation and selects a chart to be output for being displayed according to an instruction input by the user.

The display unit 215 displays the information of the chart selected by the chart selection unit 214. For example, the display unit 215 may display the correlation value of the parameters and the mapped image. The display unit 215 includes a display 208. The display unit 215 is not limited to the display 208, and may be a projector. The display unit 215 includes at least one display device of, for example, a liquid crystal display, an organic EL display, and a projector.

### 2.2 Operation

The chart display device 200 receives the laser data for each wafer and for each scan and the laser data during non-exposure from the laser device 1, and stores these laser data in the data storage unit 217. The laser data includes the pulse counts, the pulse energy, the charge voltage, the wavelength, the spectral line width, the chamber gas pressure, and the like for each wafer and for each scan.

The chart display device 200 receives the exposure condition data and exposure/non-exposure information from the exposure apparatus 4, and stores these data in the data storage unit 217. The exposure condition data includes, for example, the exposure pulse energy, the focus position Zf, and the like. The exposure/non-exposure information is information indicating whether the wafer is exposed or non-exposed. The information on the exposure start time and the exposure end time for each wafer can be used to determine whether it is during exposure or other than during exposure (during non-exposure).

The exposure/non-exposure information may include exposure information indicating that it is during exposure and non-exposure information indicating that it is during non-exposure. For example, a wafer number of a wafer to be exposed or a scan number can be used as the exposure information. Further, for example, information indicating that adjustment oscillation is being performed may be the non-exposure information. The chart display device 200 may acquire the exposure/non-exposure information directly from the exposure apparatus 4 or may acquire it via the laser device 1.

The user can select data to be displayed as a chart from the data of various parameters collected by the chart display device 200. The chart generation unit 212 of the chart display device 200 reads data matching the selected data from the data storage unit 217, and generates a chart. The chart generation unit 212 may generate a plurality of charts of different types. The chart generated by the chart generation unit 212 is displayed on the display unit 215.

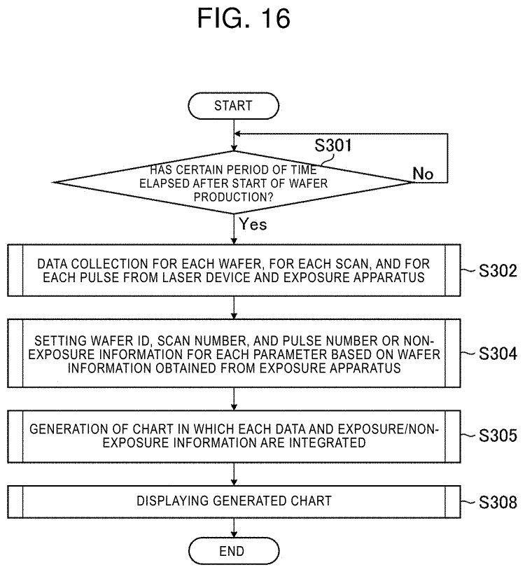

FIG. 16 is a flowchart showing an example of the main flow of processing by the chart display device 200 according to the first embodiment. The processing shown in the flowchart of FIG. 16 is realized by the processor 202 configuring the chart display device 200 executing an instruction of the program.

In step S301, the chart display device 200 determines whether or not a certain period of time has elapsed after the start of wafer production. When the determination result in step S301 is NO, the chart display device 200 repeats step S301.

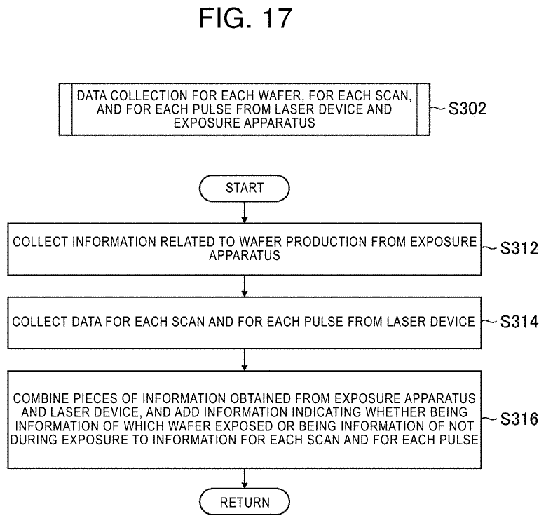

When the determination result in step S301 becomes YES as the certain period of time has elapsed after the start of wafer production, the chart display device 200 proceeds to step S302 and collects data for each wafer, for each scan, and for each pulse of the laser device 1 and the exposure apparatus 4. Thus, the chart display device 200 performs data collection from the laser device 1 and the exposure apparatus 4 at regular time intervals after the start of wafer production. Details of step S302 will be described later with reference to FIG. 17.

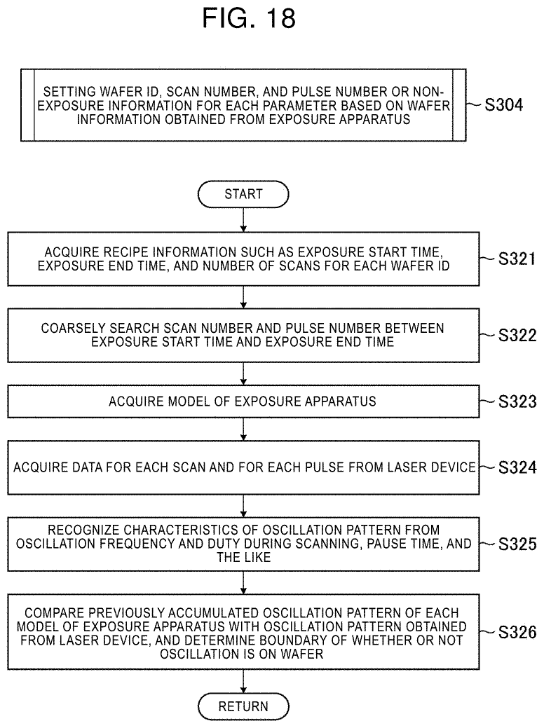

Next, in step S304, the chart display device 200 sets the wafer number, the scan number, and the pulse number, or the non-exposure information for the data of each parameter based on the wafer information obtained from the exposure apparatus 4. The wafer number may be a wafer ID for identifying each wafer. Details of step S304 will be described later with reference to FIG. 18. The data in which the wafer ID, the scan number, and the pulse number are linked represent data during wafer exposure.

The wafer ID, the scan number, and the pulse number can be exposure information indicating that it is during wafer exposure. For the data during non-exposure, non-exposure information indicating that it is during non-exposure is set. Either exposure information or non-exposure information is given to each data.

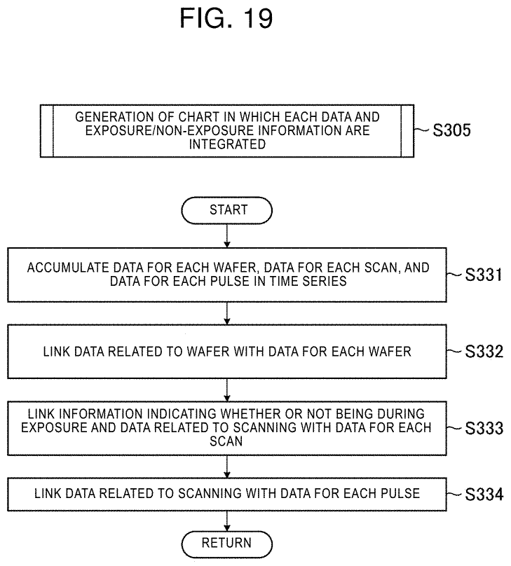

Next, in step S305, the chart display device 200 generates a chart in which each data and the exposure/non-exposure information are integrated. For example, the chart display device 200 generates a table in which data is organized by adding the exposure/non-exposure information that explicitly distinguishes between data during exposure and data during non-exposure to each record (data record) that is a data set in which data of each parameter obtained for each pulse is unitized. Details of step S305 will be described later with reference to FIG. 19.

Next, in step S308, the chart display device 200 displays the generated chart. The chart displayed in step S308 may be a data list organized in a table format, or may be a diagram in which a part or all of the data of the table is graphed or imaged.

After step S308, the flowchart of FIG. 16 ends. Here, during the operation period of the semiconductor manufacturing system 310, the flowchart of FIG. 16 may be repeatedly performed.

FIG. 17 is a flowchart showing an example of a sub-flow applied to the process of step S302 in the flowchart of FIG. 16.

In step S312, the chart display device 200 collects information about wafer production from the exposure apparatus 4. Information related to wafer production includes, for example, data such as the wafer number, the scan number, and the exposure conditions.

Next, in step S314, the chart display device 200 collects data for each scan and for each pulse from the laser device 1.

Next, in step S316, the chart display device 200 combines pieces of the information obtained from the exposure apparatus 4 and the laser device 1, and adds the attribute information, to information for each scan and for each pulse, indicating an attribute of whether being information of which wafer exposed or information of not being during exposure (information during non-exposure). That is, the chart display device 200 mainly uses the information of the exposure start time, the exposure end time, and the produced wafer ID to link the attribute information indicating the attribute of whether being information of which wafer exposed or information of not being during exposure (information during non-exposure) with the information for each scan and for each pulse. The attribute information may be referred to as classification information.

After step S316, the chart display device 200 ends the flowchart of FIG. 17 and returns to the main flow of FIG. 16.

FIG. 18 is a flowchart showing an example of a sub-flow applied to the process of step S304 in the flowchart of FIG. 16.

In step S321, the chart display device 200 acquires recipe information such as the exposure start time, the exposure end time, and the number of scans for each wafer ID from the exposure apparatus 4.

Next, in step S322, the chart display device 200 coarsely searches for a scan number and a pulse number between the exposure start time and the exposure end time from the record of the data for each parameter obtained for each pulse.

Next, in step S323, the chart display device 200 acquires information that identifies the model (unit type) of the exposure apparatus 4.

In step S324, the chart display device 200 acquires data for each scan and for each pulse from the laser device 1.

In step S325, the chart display device 200 recognizes characteristics of the oscillation pattern from the oscillation frequency and duty during scanning, pause time, and the like. Further, the chart display device 200 may recognize characteristics of the oscillation pattern in the adjustment oscillation or the running-in operation from the oscillation frequency and duty during non-scanning (during non-exposure), pause time, and the like.

Next, in step S326, the chart display device 200 compares the oscillation pattern of each model of the exposure apparatus 4 previously accumulated in the device with the oscillation pattern obtained from the laser device 1, and determines the boundary of whether or not the oscillation is on the wafer.

After step S326, the chart display device 200 ends the flowchart of FIG. 18 and returns to the main flow of FIG. 16.

FIG. 19 is a flowchart showing an example of a sub-flow applied to the process of step S305 in the flowchart of FIG. 16.

In step S331, the chart display device 200 accumulates data for each wafer, data for each scan, and data for each pulse in time series.

Next, in step S332, the chart display device 200 links the data related to the wafer with data for each wafer. The data for each wafer may be, for example, the wafer ID or average data for each wafer.

Next, in step S333, the chart display device 200 links, with the data for each scan, information indicating whether or not being during exposure and data related to scanning. The data for each scan may be, for example, data of the laser energy or E95. When the corresponding data is data during exposure, the wafer ID as data related to scanning is linked. When the corresponding data is data other than during exposure, the attribute information indicating an attribute such as “adjustment oscillation” or “running-in operation” is linked.

Next, in step S334, the chart display device 200 links the data related to scanning with data for each pulse. The data for each pulse may be, for example, data of the laser energy or E95.

After step S334, the chart display device 200 ends the flowchart of FIG. 19 and returns to the main flow of FIG. 16.

The processing shown in the flowcharts of FIGS. 16 to 19 is an example of an information processing method executed by the processor 202.

### 2.3 Example of Table Including Exposure/Non-Exposure Information

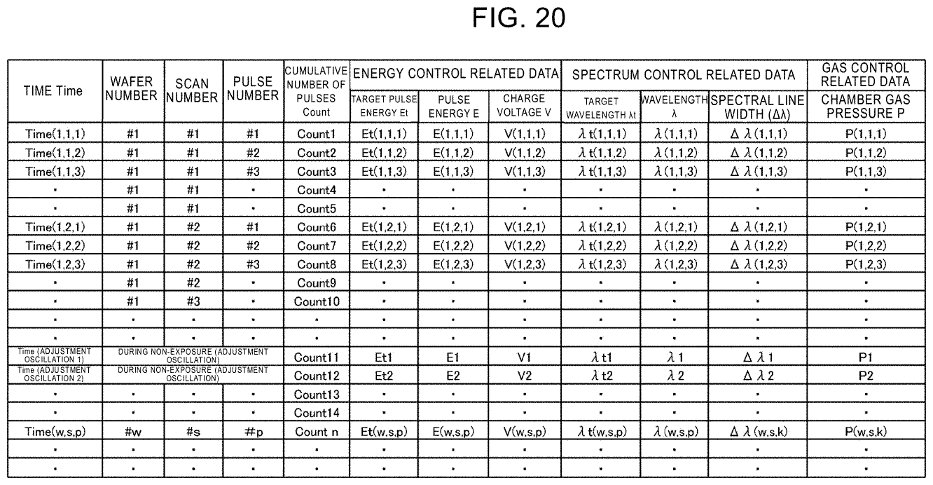

FIG. 20 shows an example of a table including exposure/non-exposure information generated by the chart display device 200. The data of various parameters collected in the chart display device 200 is linked to the time data, and the records can be arranged in time series using the time data as a key. As shown in FIG. 20, data for each wafer, for each scan, and for each pulse are arranged in time series. The time data may be data of time expressed with reference to standard time in any region. Further, the time data may be data of time representing a time difference from an arbitrary time point being as a reference. The time data in the table shown in FIG. 20 is data generated using any one of these references as a common reference.

The chart display device 200 generates a record in which data related to a plurality of parameters linked to the same time data is unitized, performs classification for distinguishing whether being data during exposure or being data during non-exposure for each record, and links the exposure/non-exposure information according to the classification.

The chart display device 200 arranges data collected by executing the flowchart shown in FIG. 13 in time series. Thus, the chart display device 200 generates a table for displaying data for each wafer, for each scan, and for each pulse as shown in FIG. 20. At this time, in the case of data on the wafer (during exposure), the wafer number is linked, but in the case of data not on the wafer (during non-exposure), the wafer number is not given, and instead, the attribute information indicating data being during non-exposure is given. Here, an example is shown in which information indicating “adjustment oscillation” is given as the attribute information indicating data being during non-exposure. The adjustment oscillation may be further classified into a plurality of types, and the attribute information indicating classification such as adjustment oscillation 1, adjustment oscillation 2, and adjustment oscillation 3 may be used. In addition to the “adjustment oscillation”, information indicating an attribute such as “running-in operation” may be used as the attribute information indicating data being during non-exposure.

The wafer number is used as the attribute information indicating data being during exposure. At least one of the wafer number, the scan number, and the pulse number can be used as the attribute information indicating data being during exposure. The table shown in FIG. 20 can be displayed as a chart in a table format on the display unit 215 of the chart display device 200. In addition, the chart display device 200 can also generate a chart by extracting data of a part of the parameters from the table shown in FIG. 20.

### 2.4 Effect

According to the chart display device 200 of the first embodiment, the attribute information indicating the classification of exposure/non-exposure is given to the data for each collected parameter, and the data is organized with the data during exposure and the data during non-exposure clearly distinguished from each other. Thus, the chart can be displayed with the data during exposure and the data during non-exposure clearly distinguished from each other.

Further, according to the chart display device 200 of the first embodiment, it is possible to extract only the data during non-exposure from the collected data and analyze the data, and to display the analysis result of the data during non-exposure. According to the chart display device 200, it is possible to distinguish the data related to the pulse light directly used in wafer production (the data during exposure) and the data related to the pulse light not directly used in wafer production such as adjustment oscillation (the data during non-exposure) from each other, to perform analysis of the respective data, and to generate analysis information of comparison between the both and of a new viewpoint.

### 2.5 Modification

The chart display device 200 may be connected to a plurality of laser devices via a network and configured to collect data from the plurality of laser devices and manage the performance of each laser device.

### 3. Second Embodiment

### 3.1 Configuration

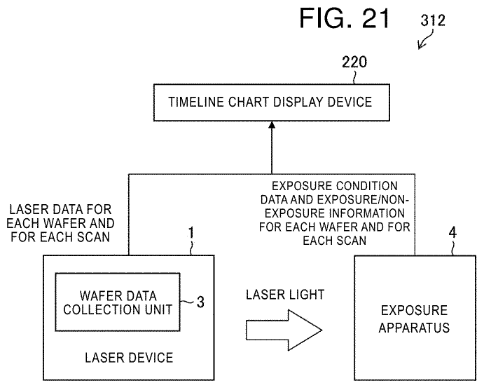

FIG. 21 schematically shows a configuration example of the semiconductor manufacturing system 312 including a timeline chart display device 220 according to a second embodiment. Differences from the first embodiment will be described.

The semiconductor manufacturing system 312 according to the second embodiment includes the timeline chart display device 220 in place of the chart display device 200 of FIG. 14. The hardware configuration of the timeline chart display device 220 may be similar to that of the chart display device 200 according to the first embodiment.

The timeline chart display device 220 may be a terminal device such as a personal computer, or may be a server connected to a network. The timeline chart display device 220 is an information processing device including a communication function for receiving various types of data, a data processing function for processing the received data, and a display function for displaying information such as a processing result of the data. The timeline chart display device 220 is an example of the “information processing device” in the present disclosure.

The timeline chart display device 220 is configured to receive data such as laser data of each wafer, of each scan, and of each pulse, exposure conditions, exposure/non-exposure information, and the like from the laser device 1 and the exposure apparatus 4.

The timeline chart display device 220 may acquire the exposure/non-exposure information directly from the exposure apparatus 4 or via the wafer data collection control unit 3 of the laser device 1. Further, the exposure/non-exposure information may be generated as the attribute information indicating a label corresponding to a classification result by classifying the data as distinguishing the period of exposure and the period of non-exposure from each other based on the time data and the recognition of the oscillation pattern by the analysis of the trigger time interval of the light emission trigger signal.

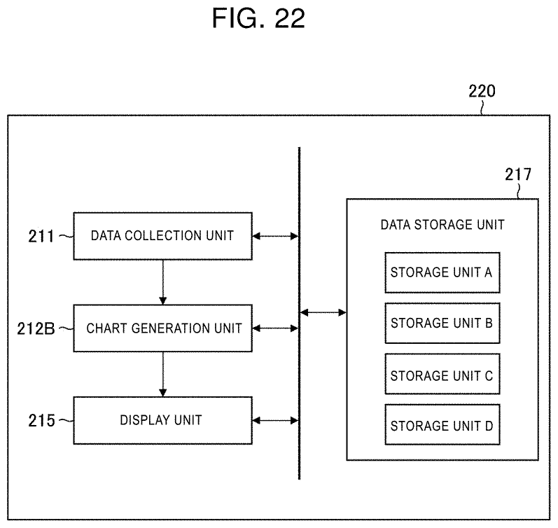

FIG. 22 is a block diagram schematically showing the function of the timeline chart display device 220. The timeline chart display device 220 includes a chart generation unit 212B in place of the chart generation unit 212 of FIG. 15. The chart generation unit 212B is realized by the processor executing instructions of the program.

The chart generation unit 212B includes a processing function of the chart generation unit 212. Further, the chart generation unit 212B generates a timeline chart including the exposure/non-exposure information. In addition to the timeline chart, the chart generation unit 212B can generate a chart for selectively displaying additional data according to other parameters.

The chart generation unit 212B may generate a plurality of types of the timeline chart.

### 3.2 Operation

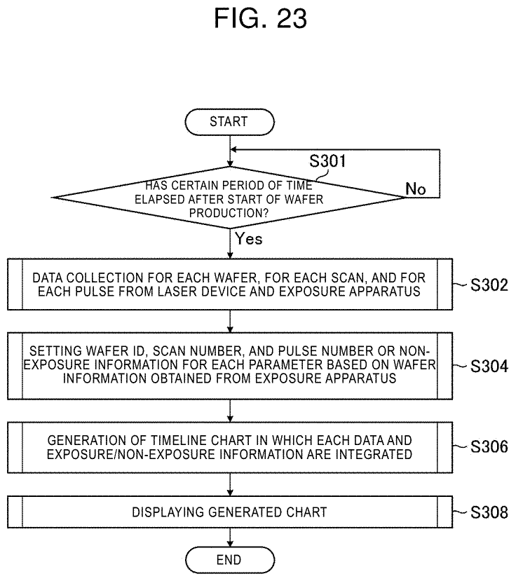

FIG. 23 is a flowchart showing an example of a main flow of processing by the timeline chart display device 220 according to the second embodiment. Differences from the flowchart of FIG. 16 will be described. The flowchart of FIG. 23 includes step S306 instead of step S305 in FIG. 16.

In step S306, the timeline chart display device 220 generates a timeline chart in which each data and the exposure/non-exposure information are integrated. Then, the timeline chart display device 220 displays the generated timeline chart (step S308).

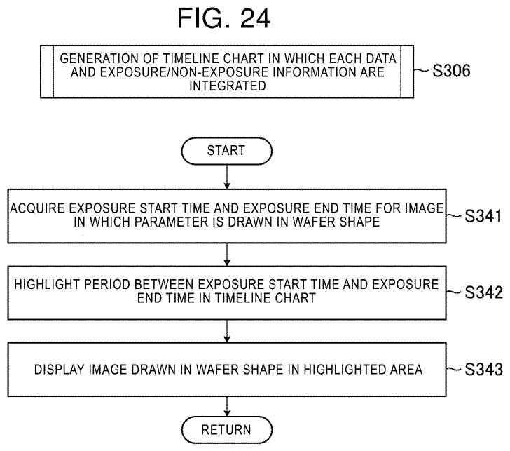

FIG. 24 is a flowchart showing an example of a sub-flow applied to the process of step S306 in the flowchart of FIG. 23.

In step S341, the timeline chart display device 220 acquires the exposure start time and the exposure end time for the image in which the parameter is drawn in the wafer shape.

Next, in step S342, the timeline chart display device 220 highlights the period between the exposure start time and the exposure end time in the timeline chart.

Further, in step S343, the timeline chart display device 220 generates display data for displaying, in the highlighted area, an image of a target parameter drawn in the wafer shape.

After step S343, the timeline chart display device 220 ends the flowchart of FIG. 24 and returns to the main flow of FIG. 23.

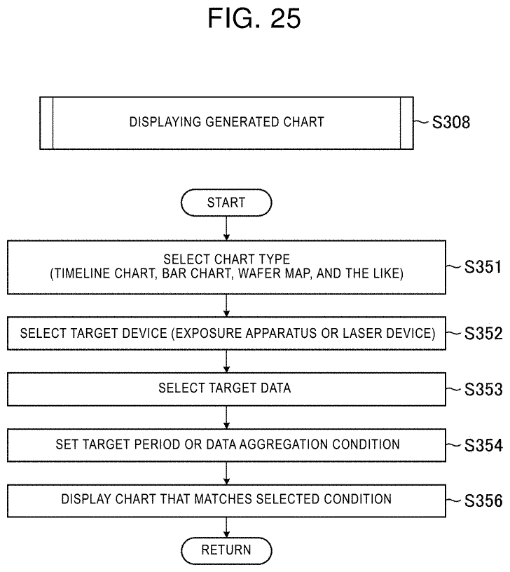

FIG. 25 is a flowchart showing an example of a sub-flow applied to the process of step S308 in the flowchart of FIG. 23.

In step S351, the timeline chart display device 220 selects the chart type to be displayed. Examples of the chart type includes a timeline chart, a bar chart, and a wafer map. The wafer map means a mapped image drawn in the wafer shape or a processed image obtained by performing filtering processing on the mapped image. The user can designate one or more desired chart types from among a plurality of chart types by operating the input device 206. The timeline chart display device 220 receives user input for chart type selection.

In step S352, the timeline chart display device 220 selects the target device (the exposure apparatus 4 or the laser device 1). The user can input information designating the model of the exposure apparatus 4 or the model of the laser device 1 by operating the input device 206. The timeline chart display device 220 receives user input for selecting the target device.

Next, in step S353, the timeline chart display device 220 selects the data to be displayed on the timeline chart display device 220. The user can input information for designating an item of data to be displayed by operating the input device 206. The timeline chart display device 220 receives user input for selecting the target data.

The target data may be, for example, a number of pulses used during exposure, average E95 for each wafer, or the like.

Next, in step S354, the timeline chart display device 220 sets a target period or a data aggregation condition. The aggregation condition may be set in advance by a program or the like, or may be appropriately set by the user operating the input device 206. The timeline chart display device 220 receives user input for designating the period or the aggregation condition.

In step S356, the timeline chart display device 220 displays a chart that matches the selected condition on the display unit 215. The processor of the timeline chart display device 220 performs display control for displaying the chart on the display unit 215.

After step S356, the timeline chart display device 220 ends the flowchart of FIG. 25 and returns to the main flow of FIG. 23.

### 3.3 Display Example of Timeline Chart

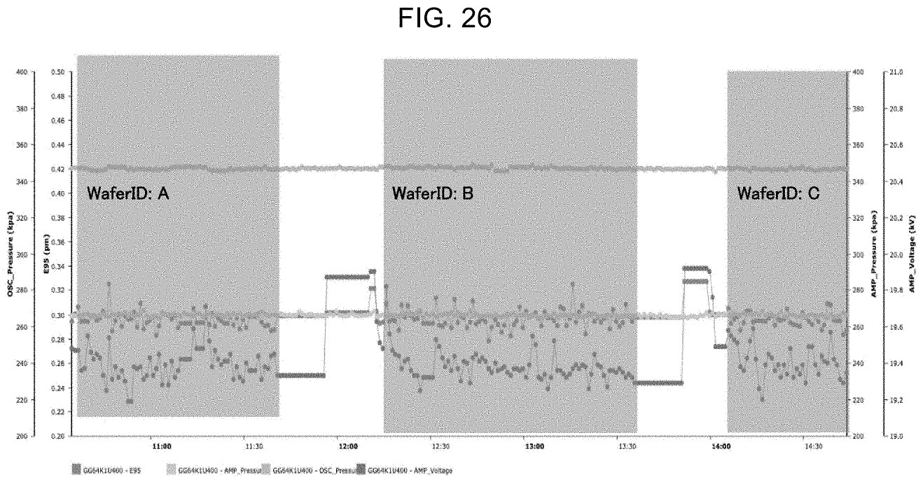

FIG. 26 is a display example of the timeline chart. The timeline chart shown in FIG. 26 is an example of the “timeline format chart” in the present disclosure. The horizontal axis and the vertical axis in FIG. 26 are the same as those in FIG. 13. According to the timeline chart display device 220 of the second embodiment, as shown in FIG. 26, information for explicitly displaying “whether or not wafer exposure is performed” is displayed on the timeline chart. Here, the period during exposure (wafer exposure period) which is divided by the exposure start time and the exposure end time of each wafer is highlighted, and further, information of the wafer ID identifying the wafer to be exposed is displayed as character information on the area corresponding to the highlighted period during exposure in a superimposed manner.

Although not shown in FIG. 26, a map image and the like in which data related to the designated parameter is drawn in the wafer shape and imaged may be additionally displayed in the highlighted area.

In addition, the area corresponding to the non-exposure period may be highlighted in another display color distinguished from the highlight display in the wafer exposure period, that is, color-coded display may be performed.

### 3.4 Effect

According to the timeline chart display device 220 of the second embodiment, by highlighting the period during exposure of each wafer in the display of the timeline chart and displaying the information of the wafer ID superimposed on the display, it is possible to easily confirm which wafer the change of the parameter is at the time of production. In addition, it is possible to easily distinguish a change in a parameter during exposure and a change in a parameter other than during exposure (during non-exposure) from each other. Thus, it is possible to confirm the parameters being adjusted other than during exposure from changes in parameters other than during exposure.

### 4. Third Embodiment

### 4.1 Configuration

The hardware configuration of the chart display device according to the third embodiment is similar to that of the first embodiment.

### 4.2 Operation

The chart display device according to the third embodiment performs data collection for each exposure time and each non-exposure time using the collected data. The chart display device generates charts of data aggregated for each exposure time and for each non-exposure time.

As described with reference to FIG. 20, since the record of the data of each parameter obtained from devices such as the laser device 1 and the exposure apparatus 4 is given with the exposure/non-exposure information as the attribute information indicating the classification of exposure/non-exposure, it is possible to easily generate a chart in which data during exposure to which the exposure information is given and data during non-exposure to which the non-exposure information is given are separately aggregated, respectively.

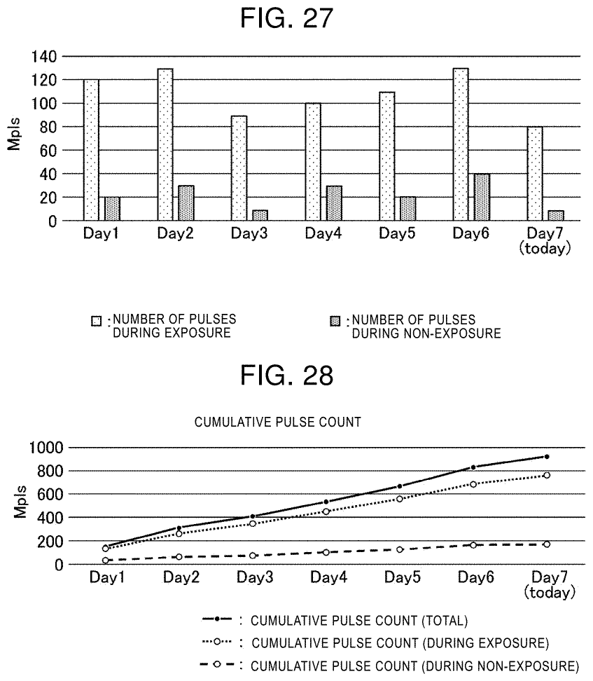

FIG. 27 shows an example of a dayline chart obtained by separately aggregating the number of pulses during exposure and the number of pulses during non-exposure. The horizontal axis represents date, and the vertical axis represents the number of pulses per day. The unit is megapulse (Mpls). According to the chart display device of the third embodiment, as shown in FIG. 27, the number of pulses during exposure and the number of pulses during non-exposure can be analyzed separately, and the analysis result can be displayed on the display unit 215. The dayline chart shown in FIG. 27 is an example of the “dayline format chart” in the present disclosure.

### 4.3 Effect

According to the chart display device of the third embodiment, it is possible to collect only the parameters used in wafer production by aggregating data during exposure. This makes it possible to accurately grasp the degree of influence of the parameters on wafer production. Further, since the data during non-exposure does is independent of the recipe at the time of wafer production, analysis of only the data during non-exposure is useful for accurately grasping aging degradation and the like of the laser device 1.

### 5. Fourth Embodiment

### 5.1 Configuration

The hardware configuration of the chart display device according to the fourth embodiment is similar to that of the first embodiment.

### 5.2 Operation

The chart display device according to the fourth embodiment performs data aggregation for each exposure time and each non-exposure time using the collected data. The chart display device generates charts aggregated for each exposure time and for each non-exposure time.

FIG. 28 shows another example of a dayline chart obtained by separately aggregating the number of pulses during exposure and the number of pulses during non-exposure. The horizontal axis represents date, and the vertical axis represents the cumulative number of pulses. According to the chart display device of the fourth embodiment, as shown in FIG. 28, the cumulative number of pulses during exposure, the cumulative number of pulses during non-exposure, and the total cumulative number of pulses during exposure and non-exposure can be graphed and simultaneously displayed on the display unit 215. The dayline chart shown in FIG. 28 is an example of the “dayline format chart” in the present disclosure.

### 5.3 Effect

According to the chart display device of the fourth embodiment, it is possible to accurately grasp the transition of the cumulative number of pulses used for production and pulses used for adjustment other than production.

### 6. Fifth Embodiment

### 6.1 Configuration

The hardware configuration of a timeline chart display device 250 according to a fifth embodiment may be similar to that of the chart display device 200 according to the first embodiment.

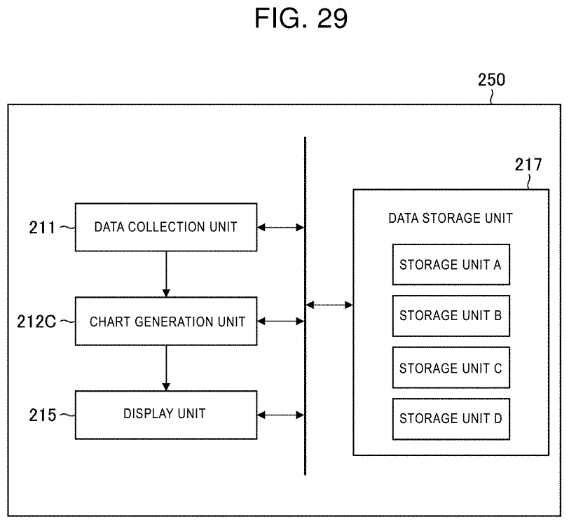

FIG. 29 is a block diagram schematically showing the function of the timeline chart display device 250 according to the fifth embodiment. Differences from FIG. 14 will be described.

The timeline chart display device 250 includes a chart generation unit 212C in place of the chart generation unit 212. The chart generation unit 212C includes a processing function similar to that of the chart generation unit 212. Further, the chart generation unit 212C generates a timeline chart in which various types of data and the exposure/non-exposure information are integrated. The chart generation unit 212C further generates a display chart for additionally displaying a wafer mapped chart according to other parameters. The chart generation unit 212C may generate a plurality of types of charts. The chart generation unit 212C may generate a chart showing the state of parameters during non-exposure using only data obtained from adjustment oscillation during non-exposure.

### 6.2 Operation

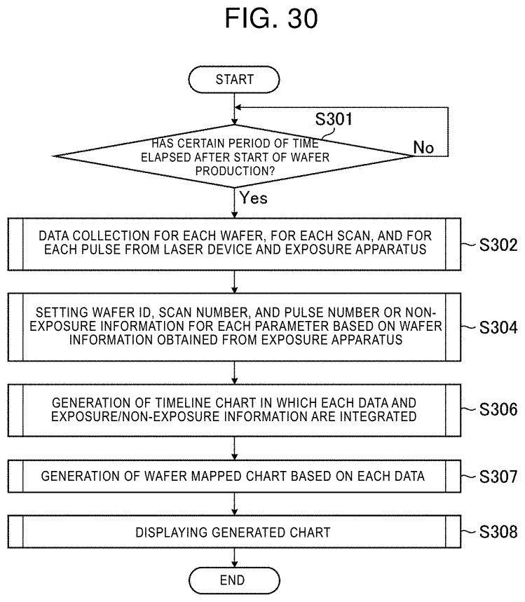

FIG. 30 is a flowchart showing an example of the main flow of the timeline chart display device 250. Differences from the flowchart of FIG. 23 will be described. The flowchart of FIG. 30 includes step S307 between step S306 and step S308 in FIG. 23.

In step S307, the timeline chart display device 250 generates a wafer mapped chart based on each of the data. The wafer mapped chart refers to a chart in the form of an image drawing “data in the wafer shape” described in step S203 of FIG. 8 or a processed image described in step S205 of FIG. 12.

Further, the timeline chart display device 250 can extract only the data obtained from the adjustment oscillation during non-exposure from the collected data group, and generate a chart using only the data during the adjustment oscillation.

The timeline chart display device 250 displays the generated chart on the display 208 (step S308).

### 6.3 Display Example of Timeline Chart and Wafer Mapped Chart

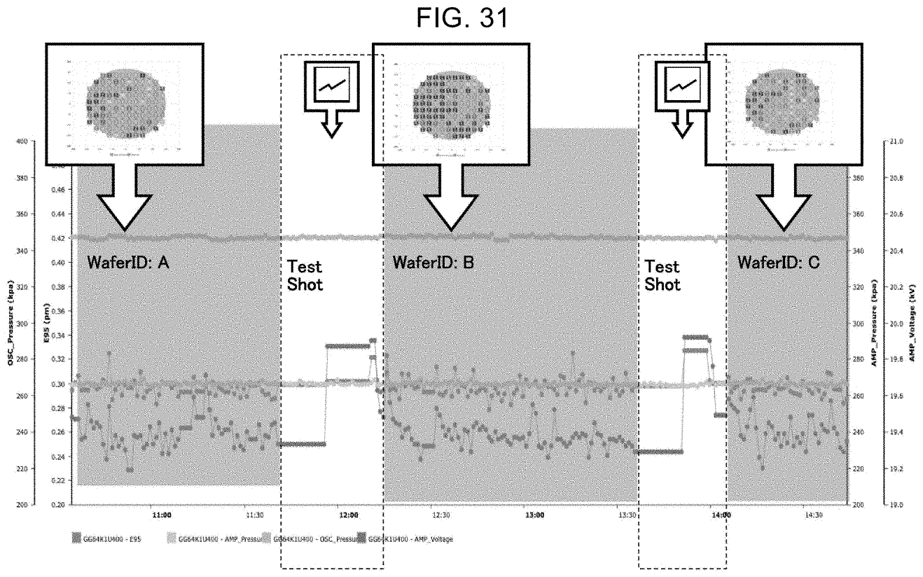

FIG. 31 is a display example of a chart displayed by the timeline chart display device 250 according to the fifth embodiment. As shown in FIG. 31, the timeline chart and the wafer mapped chart are displayed together (simultaneously) on the display 208. In the timeline chart of FIG. 31, similarly to FIG. 26, the area of the exposure period is highlighted so as to explicitly differentiate between the exposure period and the non-exposure period of the wafer, and information of the corresponding wafer ID is attached. Further, in the display example of FIG. 31, a chart of data related to test shots (during non-exposure) generated on the basis of data only during non-exposure is also displayed together. The test shot include the concepts of “adjustment oscillation” and “running-in operation.” In the area of the non-exposure period in the timeline chart, character information indicating that the non-exposure period in which the “test shot” has been performed is displayed in a superimposed manner.

The data represented by the timeline can also be displayed in the form of a wafer map. By showing the data at the same time after the start of exposure for each wafer, it is possible to simultaneously confirm the change of the data in the timeline and the change in the form of the wafer map.

Further, by selecting a specific wafer mapped chart from the chart display as shown in FIG. 31, the wafer mapped chart according to the selection can be displayed on the forefront of the display screen. The user can perform operation of selecting a desired chart from the input device 206.

Not limited to the wafer mapped chart, the user may select a chart of test shots. As a result, it is possible to generate a chart in which only data obtained from the test shots is extracted. For example, when the user performs click operation or touch operation for selecting an area of the “test shot” which is a non-exposure period on the screen of the chart display as shown in FIG. 31, a chart generated based on the data of the test shot is displayed on the screen of the display unit 215.

### 6.4 Display Example of Chart Generated Using Data During Non-Exposure

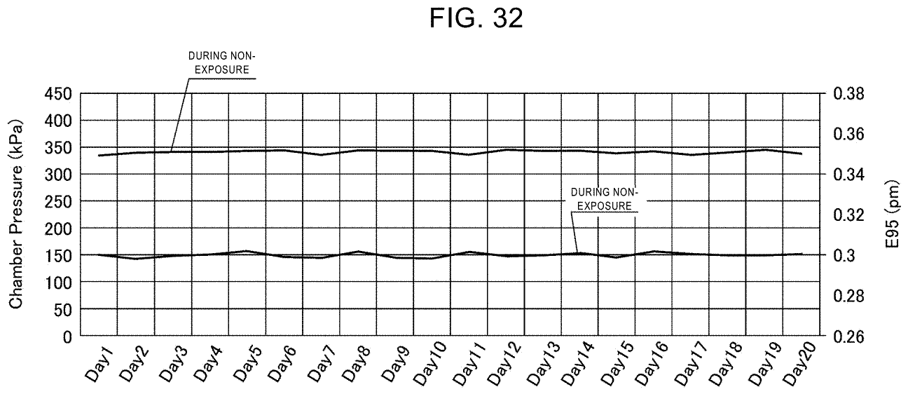

FIG. 32 is a display example of a chart generated from the data only during non-exposure. The horizontal axis represents date (days), and the vertical axis represents the chamber gas pressure and E95. The graph shown on the upper side of FIG. 32 shows the transition of the representative value of the chamber gas pressure during non-exposure. The representative value may be, for example, an average value per day. The graph shown on the lower side of FIG. 32 shows the transition of the representative value of E95 during non-exposure. According to the timeline chart display device 250, as shown in FIG. 32, it is possible to extract data only during non-exposure in a long span and display the extracted data as a chart.

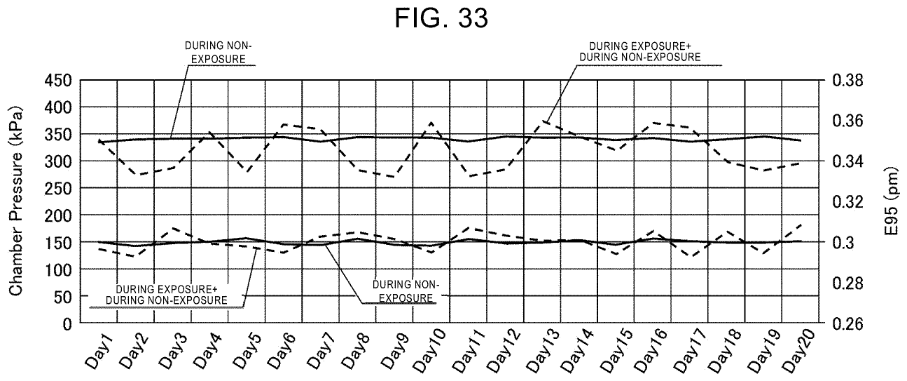

FIG. 33 is a display example in which a chart of data obtained by combining data during non-exposure and data during exposure and a chart of data only during non-exposure are simultaneously displayed. In FIG. 33, a chart of data of “during non-exposure+during exposure” is added to the chart display shown in FIG. 32.

According to the timeline chart display device 250, as shown in FIG. 33, it is also possible to mix data of “during non-exposure+during exposure” and data only during non-exposure, and display the data extracted in a long span as a chart.

### 6.5 Effect

According to the timeline chart display device 250 according to the fifth embodiment, as shown in FIG. 31, it is possible to display a chart easy to understand in which the period during exposure and the period during non-exposure are clearly distinguished from each other.

Further, according to the timeline chart display device 250, as shown in FIG. 32, by extracting data only during non-exposure and displaying the chart, it is possible to grasp the state of the laser device 1 under the same conditions which does not depend on the production conditions of the wafer, and thus it is possible to obtain data useful for predicting the lifetime.

On the other hand, as shown in FIG. 33, when the data during exposure and during non-exposure are mixed, the variation of the data can be grasped.

### 7. Laser Oscillation During Non-Exposure

The laser oscillation during non-exposure includes running-in operation and various types of test oscillation for the laser device 1 in addition to adjustment oscillation for the exposure apparatus 4. In the adjustment oscillation, a plurality of patterns are determined depending on the model (unit type) of the exposure apparatus 4, and oscillation is performed in the plurality of patterns. Therefore, the attribute information may be associated with each pattern by finely classifying the attribute of the adjustment oscillation for each pattern based on the data of the oscillation pattern for each model. During the adjustment oscillation, the laser oscillation is performed in a state in which the shutter (not shown) of the laser device 1 is opened.

The running-in operation may include, for example, passivation operation performed to improve the performance of the laser device 1, running-in operation during gas exchange, and the like. The condition of the running-in operation may be predetermined by the model of the laser device 1, or may be appropriately designated. Here, in the running-in operation, the laser oscillation is performed in a state in which the shutter of the laser device 1 is closed.

Attribute information corresponding to the type of running-in operation or the type of test oscillation may be associated with the data during non-exposure.

### 8. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. An information processing device comprising a processor and a storage device,
the processor being configured:
to acquire data for each parameter provided from each of a light source device which generates pulse light and an exposure apparatus which performs exposure on a wafer with the pulse light output from the light source device, and time data associated with the data;
to perform classification, based on the acquired data and time data, for each record of the data associated with same time data for distinguishing whether being data during exposure in which the wafer is irradiated with the pulse light or being data during non-exposure other than during the exposure;
to associate attribute information indicating an attribute according to the classification with each of the records;
to cause the storage device to store the data and the time data associated with the attribute information; and
to generate a chart using data read from the storage device.

2. The information processing device according to claim 1, further comprising a display,
wherein the processor causes the display to display the chart.

3. The information processing device according to claim 1,
wherein the processor generates a table in which the records are arranged in time series based on the time data.

4. The information processing device according to claim 1,
wherein the processor generates the records in which data related to a plurality of parameters is unitized based on the time data.

5. The information processing device according to claim 1,
wherein the attribute information includes exposure information indicating data being during the exposure and non-exposure information indicating data being during the non-exposure, and
the processor associates each of the records with the exposure information or the non-exposure information.

6. The information processing device according to claim 5,
wherein the data provided from the exposure apparatus includes wafer identification information for identifying the wafer to be exposed, a scan number for identifying a position of a scan region in the wafer, exposure start time and exposure end time for each wafer, and data related to an exposure condition, and
the processor uses, as the exposure information, at least one of wafer number as the wafer identification information and the scan number.

7. The information processing device according to claim 5,
wherein the non-exposure information includes information indicating data being during adjustment oscillation.

8. The information processing device according to claim 1,
wherein the chart is a timeline format chart.

9. The information processing device according to claim 8,
wherein the timeline format chart includes highlight display indicating whether being a period during the exposure or a period during the non-exposure in a distinguishing manner.

10. The information processing device according to claim 8,
wherein the processor causes wafer identification information identifying the wafer to be exposed to be displayed in an area corresponding to a period during the exposure in the timeline format chart in a superimposed manner.

11. The information processing device according to claim 8,
wherein the processor generates a wafer shape mapped image using the data during the exposure for each of the wafers to be exposed, and displays the mapped image in an area corresponding to a period during the exposure in the timeline format chart in a superimposed manner.

12. The information processing device according to claim 8,
wherein the processor causes character information indicating being during the non-exposure to be displayed in an area corresponding to a period during the non-exposure in the timeline format chart in a superimposed manner.

13. The information processing device according to claim 8,
wherein the processor generates a chart related to a parameter during the non-exposure only using the data during the non-exposure among the data during the non-exposure and the data during the exposure, and causes the chart related to the parameter during the non-exposure to be displayed in an area corresponding to a period during the non-exposure in the timeline format chart in a superimposed manner.

14. The information processing device according to claim 1,
wherein the chart is a dayline format chart.

15. The information processing device according to claim 14,
wherein the dayline format chart is a chart showing transition of a number of pulses.

16. The information processing device according to claim 14,
wherein the dayline format chart is a chart displaying transition of a number of pulses during the exposure and transition of a number of pulses during the non-exposure in a distinguishing manner.

17. The information processing device according to claim 14,
wherein the dayline format chart is a chart showing transition of a cumulative number of pulses.

18. The information processing device according to claim 1, further comprising a display and an input device,
wherein the processor receives input of information designating a type of a chart to display on the display, and causes the display to display the designated type of the chart in accordance with the information input from the input device.

19. An information processing method to be executed by a processor, the method comprising:
acquiring data for each parameter provided from each of a light source device which generates pulse light and an exposure apparatus which performs exposure on a wafer with the pulse light output from the light source device, and time data associated with the data;
performing classification, based on the acquired data and time data, for each record of the data associated with same time data for distinguishing whether being data during exposure in which the wafer is irradiated with the pulse light or being data during non-exposure other than during the exposure;
associating attribute information indicating an attribute according to the classification with each of the records;
causing a storage device to store the data and the time data associated with the attribute information; and
generating a chart using data read from the storage device.

20. A semiconductor manufacturing system comprising:
a light source device which generates pulse light;
an exposure apparatus which performs exposure on a wafer with the pulse light output from the light source device; and
an information processing device,
the information processing device including a processor and a storage device, and
the processor being configured:
to acquire data for each parameter provided from each of a light source device which generates pulse light and an exposure apparatus which performs exposure on a wafer with the pulse light output from the light source device, and time data associated with the data;
to perform classification, based on the acquired data and time data, for each record of the data associated with same time data for distinguishing whether being data during exposure in which the wafer is irradiated with the pulse light or being data during non-exposure other than during the exposure;
to associate attribute information indicating an attribute according to the classification with each of the records;
to cause the storage device to store the data and the time data associated with the attribute information; and
to generate a chart using data read from the storage device.
